(19) United States
(12) Patent Application Publication
(10) Pub. No.: US 2022/0204851 A1
(43) Pub. Date: Jun. 30, 2022

(54) LIQUID CRYSTAL POLYMER FILM AND SUBSTRATE FOR HIGH-SPEED COMMUNICATION

(71) Applicant: FUJIFILM Corporation, Tokyo (JP)

(72) Inventors: Takeaki SAWAYA, Shizuoka (JP); Takeo KIDO, Shizuoka (JP); Akira YAMADA, Shizuoka (JP)

(73) Assignee: FUJIFILM Corporation, Tokyo (JP)

(21) Appl. No.: 17/696,888

(22) Filed: Mar. 17, 2022

Related U.S. Application Data
(63) Continuation of application No. PCT/JP2020/036230, filed on Sep. 25, 2020.

(30) Foreign Application Priority Data
Sep. 27, 2019 (JP) 2019-176757
Sep. 24, 2020 (JP) 2020-159471

(51) Int. Cl. C09K 19/38

(52) U.S. Cl. CPC C09K 19/38

(57) ABSTRACT

The present invention provides a liquid crystal polymer film having good smoothness and surface properties and having reduced anisotropy. In addition, the present invention provides a substrate for high-speed communication relating to the liquid crystal polymer film. The liquid crystal polymer film of the present invention includes a liquid crystal polymer component and at least one component selected from the group consisting of an olefin component, a cross-linking component, and a compatible component.

### CROSS-REFERENCE TO RELATED APPLICATIONS

This application is a Continuation of PCT International Application No. PCT/JP2020/036230 filed on Sep. 25, 2020, which claims priority under 35 U.S.C. § 119(a) to Japanese Patent Application No. 2019-176757 filed on Sep. 27, 2019 and Japanese Patent Application No. 2020-159471 filed on Sep. 24, 2020. Each of the above applications is hereby expressly incorporated by reference, in its entirety, into the present application.

### BACKGROUND OF THE INVENTION

### 1. Field of the Invention

The present disclosure relates to a liquid crystal polymer film and a substrate for high-speed communication.

### 2. Description of the Related Art

Higher frequencies and wider bands than ever before have been used in a 5th generation (5G) mobile communication system, which is considered to be next-generation communication technology. Therefore, as a substrate film for a circuit board for the 5G mobile communication system, a film having low dielectric constant and low dielectric loss tangent characteristics is required, and each company proceeds with development using various materials. One of the substrate films is a liquid crystal polymer film. The liquid crystal polymer (LCP) film has a lower dielectric constant and a lower dielectric loss tangent than general polyimides, glass epoxy films, and the like in a 4th generation (4G) mobile communication system.

Since the liquid crystal polymer has a rod-shaped molecular structure, the liquid crystal polymer has strong aligning properties, and in a case where the liquid crystal polymer is melt-extruded, the liquid crystal polymer tends to be aligned in a longitudinal direction (Machine Direction direction; MD direction) due to shear stress by a die slit, melt draw, and the like. Therefore, the liquid crystal polymer film manufactured by melt extrusion tends to be a uniaxially aligned film. Probably due to the strong aligning properties of the liquid crystalline polymer, the obtained liquid crystal polymer film is liable to have a large number of wrinkles and surface irregularities, and surface properties and smoothness of a surface are liable to be deteriorated. As a film substrate for a high-frequency circuit board, since a decrease in surface properties and smoothness leads to a decrease in yield and reliability of the circuit formed on the film, studies for improving the surface properties of the liquid crystal polymer film are underway.

For example, WO2013/146174A proposes a method of stretching a film-formed film.

### SUMMARY OF THE INVENTION

In the manufacturing method of WO2013/146174A, an effect of reducing thickness unevenness can be expected to some extent by stretching after film formation, but the manufacturing method is insufficient as a method for improving surface properties and smoothness of the surface.

In addition, since the liquid crystal polymer is easily aligned, the liquid crystal polymer film often has strong anisotropy in a molding direction. Due to such anisotropy, in steps of a manufacturing process to obtain a specific product using the liquid crystal polymer film, and the like, on a surface of the liquid crystal polymer film, wrinkles or the like, which do not exist immediately after the liquid crystal polymer film is manufactured, may be newly generated.

The present invention has been made in view of the above-described circumstances, and an object of the present invention is to provide a liquid crystal polymer film having good smoothness and surface properties and having reduced anisotropy.

Another object is to provide a substrate for high-speed communication relating to the liquid crystal polymer film.

The inventors of the present invention have conducted intensive studies to solve the above-described problems, and as a result, have found that the above-described problems can be solved by the following configurations.

[1]

A liquid crystal polymer film comprising:

a liquid crystal polymer component; and

at least one component selected from the group consisting of an olefin component, a cross-linking component, and a compatible component.

[2]

The liquid crystal polymer film according to [1],

in which the liquid crystal polymer film includes the liquid crystal polymer component, the olefin component, and the compatible component.

[³]

The liquid crystal polymer film according to [1] or [2], in which the liquid crystal polymer film includes the liquid crystal polymer component, the olefin component, the compatible component, and a heat stabilizer.

[4]

The liquid crystal polymer film according to any one of [1] to [3], in which the liquid crystal polymer component is a thermotropic liquid crystal polymer.

[5]

The liquid crystal polymer film according to any one of [1] to [4], in which the liquid crystal polymer film includes the olefin component, and a content of the olefin component in the liquid crystal polymer film is 0.1% to 40% by mass with respect to a total mass of the liquid crystal polymer film.

[6]

The liquid crystal polymer film according to any one of [1] to [5], in which the liquid crystal polymer film includes the olefin component, the olefin component forms a dispersed phase in the liquid crystal polymer film, and an average dispersion diameter of the dispersed phase is 0.01 to 10 μm.

[7]

The liquid crystal polymer film according to [6], in which, in the liquid crystal polymer film, in a case where a length of the dispersed phase in a width direction is defined as Lx and a length of the dispersed phase in a longitudinal direction is defined as Ly, Expression (1M is satisfied.

$$0.10 \leq Ly / Lx \leq 10.0 . \qquad ( 1 A )$$

[8]

The liquid crystal polymer film according to [6] or [7], in which, in the liquid crystal polymer film, in a case where a length of the dispersed phase in a width direction is defined as Lx, a length of the dispersed phase in a longitudinal direction is defined as Ly, and a length of the dispersed phase in a thickness direction is defined as Lz, Expression (2A) and Expression (3A) are satisfied,

$$0.010 \leq Lz / Lx \leq 1. \qquad ( 2 A )$$

$$0.01 0 \leq Lz / Ly \leq 1. 0 . \qquad ( 3 A )$$

[9]

The liquid crystal polymer film according to any one of [1] to [8], in which, in a case where a viscosity of the liquid crystal polymer film at a temperature lower than a melting point of the liquid crystal polymer film by 30° C. is defined as η(Tm−30° C.) and a viscosity of the liquid crystal polymer film at a temperature higher than the melting point of the liquid crystal polymer film by 30° C. is defined as η(Tm+30° C.), Expression (4A) is satisfied,

$$η ( T m + 30 ° C . ) / η ( Tm - 30 ° C . ) \geq 0.020 . \qquad ( 4 A )$$

[10]

The liquid crystal polymer film according to any one of [1] to [9],

in which MFRs of a component A and a component B satisfy a relationship represented by Expression (5A), the MFRs of the component A and the component B being obtained by performing, in the following order,
a step of immersing the liquid crystal polymer film in dichloromethane in an amount of 1000 times a mass of the liquid crystal polymer film to produce an eluate in which a soluble component of the liquid crystal polymer film to the dichloromethane is eluted in the dichloromethane,
a step of filtrating the eluate to be separated into the component A, which is a residue, and a filtrate,
a step of dropwise adding the filtrate to ethanol to precipitate a precipitate in the ethanol, and
a step of filtrating the ethanol to be separated into the component B, which is a residue, and a filtrate,

$$0.10 \leq M F {R}^{B} / MF {R}^{A} \leq 10.0 \qquad ( 5 A )$$

MFR^{A}: MFR of the component A at a load of 5 kgf at the melting point of the liquid crystal polymer film

MFR^{B}: MFR of the component B at a load of 5 kgf at the melting point of the liquid crystal polymer film.

[11]

The liquid crystal polymer film according to any one of [1] to [10], in which the olefin component is polyethylene.

[12]

The liquid crystal polymer film according to any one of [1] to [11], in which a surface roughness Ra is less than 430 nm.

[13]

A substrate for high-speed communication comprising:

the liquid crystal polymer film according to any one of [1] to [12].

According to the present invention, it is possible to provide a liquid crystal polymer film having good smoothness and surface properties and having reduced anisotropy.

In addition, it is possible to provide a substrate for high-speed communication relating to the liquid crystal polymer film.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

In notations for a group (atomic group) in the present specification, in a case where the group is cited without specifying whether it is substituted or unsubstituted, the group includes both a group having no substituent and a group having a substituent as long as this does not impair the spirit of the present invention. For example, an “alkyl group” includes not only an alkyl group having no substituent (unsubstituted alkyl group), but also an alkyl group having a substituent (substituted alkyl group). In addition, an “organic group” in the present specification refers to a group including at least 1 carbon atom.

In the present specification, a (meth)acrylic resin represents an acrylic resin and a methacrylic resin.

In the present specification, in a case where the liquid crystal polymer film has an elongated shape, a width direction of the liquid crystal polymer film means a lateral direction and a transverse direction (TD) direction, and a length direction means a longitudinal direction and an MD direction of the liquid crystal polymer film.

In the present specification, for each component, one kind of substance corresponding to each component may be used alone, or two or more kinds thereof may be used in combination. Here, in a case where two or more kinds of substances are used in combination for each component, the content of the component indicates the total content of two or more substances, unless otherwise specified.

In the present specification, “to” is used to refer to a meaning including numerical values denoted before and after “to” as a lower limit value and an upper limit value.

The liquid crystal polymer film according to an embodiment of the present invention includes a liquid crystal polymer component and at least one component selected from the group consisting of an olefin component, a cross-linking component, and a compatible component.

The mechanism for solving the problems of the present invention by satisfying the above-described configuration is not entirely clear, but the present inventors speculate as follows.

That is, the liquid crystal polymer film according to the embodiment of the present invention includes a specific component (at least one component selected from the group consisting of an olefin component, a cross-linking component, and a compatible component) in addition to the liquid crystal polymer component. The liquid crystal polymer component has a large temperature dependence of viscosity, and local viscosity differences are likely to occur in a case of producing the liquid crystal polymer film. Therefore, it tends to be a factor of deterioration of surface properties or smoothness of the liquid crystal polymer film. Here, it is considered that the presence of the specific component with the liquid crystal polymer component alleviates the above-described viscosity difference and alleviates stress caused by the above-described viscosity difference, thereby improving the surface properties and the smoothness.

It is considered that the presence of the specific component also alleviates an alignment of the liquid crystal polymer component. In addition, even in a case where the alignment occurs, it is considered that local shape changes of the liquid crystal polymer film based on the alignment are absorbed by the specific component.

It is considered that the effects of the present invention are realized by an action based on such a specific component.

Hereinafter, a case where at least one of the smoothness, the surface properties, or the suppression of anisotropy in the liquid crystal polymer film according to the embodiment of the present invention is more excellent is also referred to as that the effects of the present invention are more excellent.

[Component]

First, the components of the liquid crystal polymer film according to the embodiment of the present invention will be described.

[Liquid Crystal Polymer Component]

The liquid crystal polymer film according to the embodiment of the present invention includes a liquid crystal polymer component.

The liquid crystal polymer component is preferably a melt-moldable liquid crystal polymer.

The liquid crystal polymer component is preferably a thermotropic liquid crystal polymer. The thermotropic liquid crystal polymer means a polymer which exhibits liquid crystallinity in a predetermined temperature range.

The thermotropic liquid crystal polymer is not particularly limited as long as it is a melt-moldable liquid crystal polymer, and examples thereof include a thermoplastic liquid crystal polyester and a thermoplastic polyester amide with an amide bond introduced into the thermoplastic liquid crystal polyester.

As the liquid crystal polymer, a thermoplastic liquid crystal polymer described in WO2015/064437A can be used.

As the liquid crystal polymer component, a commercially available product may be used, and examples thereof include “LAPEROS” manufactured by Polyplastics Co., Ltd., “Vectra” manufactured by Celanese Corporation, “UENO LCP” manufactured by UENO FINE CHEMICALS INDUSTRY, LTD., “SUMIKA SUPER LCP” manufactured by Sumitomo Chemical Company, “Xydar” manufactured by ENEOS Corporation, and “Siveras” manufactured by TORAY INDUSTRIES, INC.

The liquid crystal polymer component may form a chemical bond with a cross-linking component, compatible component (reactive compatibilizer), or the like described later in the liquid crystal polymer film. The same applies to components other than the liquid crystal polymer component.

The content of the liquid crystal polymer component is preferably 40% to 99.9% by mass, more preferably 60% to 99% by mass, and particularly preferably 80% to 90% by mass with respect to the total mass of the liquid crystal polymer film.

[Specific Component]

The liquid crystal polymer film according to the embodiment of the present invention includes at least one component (specific component) selected from the group consisting of an olefin component, a cross-linking component, and a compatible component.

The present inventors have found that, by kneading the specific component into the liquid crystal polymer component, shear viscosity, alignment of the liquid crystal polymer component, and/or domain size formed by the liquid crystal polymer component can be controlled, and the effects of the present invention can be realized.

Among these, the liquid crystal polymer film according to the embodiment of the present invention preferably includes at least an olefin component together with the liquid crystal polymer component, and more preferably includes at least an olefin component and a compatible component.

(Olefin Component)

In the present specification, the olefin component is intended to be a resin (polyolefin resin) having a repeating unit based on an olefin.

The olefin component may be linear or branched. In addition, the olefin component may have a cyclic structure such as a polycycloolefin.

Examples of the olefin component include polyethylene, polypropylene (PP), polymethylpentene (TPX and the like manufactured by Mitsui Chemicals, Inc.), hydrogenated polybutadiene, a cycloolefin polymer (COP, Zeonor and the like manufactured by ZEON CORPORATION), and a cycloolefin copolymer (COC, APEL and the like manufactured by Mitsui Chemicals, Inc.).

The polyethylene may be either high density polyethylene (HDPE) or low density polyethylene (LDPE). In addition, the polyethylene may be linear low density polyethylene (LLDPE).

The olefin component may be a copolymer of an olefin and a copolymerization component other than the olefin, such as acrylate, methacrylate, styrene, and/or a vinyl acetate-based monomer.

Examples of the olefin component as the above-described copolymer include a styrene-ethylene/butylene-styrene copolymer (SEBS). SEBS may be hydrogenated.

However, from the viewpoint that the effects of the present invention are more excellent and a low dielectric loss tangent is also excellent, it is preferable that a copolymerization ratio of the copolymerization component other than the olefin is small, and it is more preferable that the copolymerization component is not included. For example, the content of the above-described copolymerization component is preferably 0% to 40% by mass, more preferably 0% to 5% by mass, and still more preferably 0% to 0.5% by mass with respect to the total mass of the olefin component. A component (compatible component and the like) described later may include the copolymerization component outside the above-described preferred content range.

In addition, it is preferable that the olefin component does not substantially include a reactive group described later, and for example, the content of a repeating unit having a reactive group is preferably 0% to 3% by mass, more preferably 0% to 0.3% by mass, and particularly preferably 0% to 0.03% by mass with respect to the total mass of the olefin component. A component (compatible component and the like) described later may include the repeating unit having a reactive group outside the above-described preferred content range.

From the viewpoint that the effects of the present invention are more excellent and the low dielectric loss tangent is also excellent, the olefin component in the present invention is preferably polyethylene, COP, or COC, more preferably polyethylene, and particularly preferably low density polyethylene (LDPE).

From the viewpoint of a melt flow rate described later, the molecular weight of the olefin component in the present invention can be appropriately selected.

From the viewpoint that surface properties of the liquid crystal polymer film are more excellent, the content of the olefin component is preferably 0.1% by mass or more, more preferably 5% by mass or more, and particularly preferably 10% by mass or more with respect to the total mass of the liquid crystal polymer film.

From the viewpoint that smoothness of the liquid crystal polymer film is more excellent, the upper limit of the above-described content is preferably 50% by mass or less, more preferably 40% by mass or less, particularly preferably 25% by mass or less, and most preferably 15% by mass or less. In addition, in a case where the content of the olefin component is 50% by mass or less, thermal deformation temperature can be easily raised sufficiently and solder heat resistance can be improved.

(Cross-Linking Component)

The cross-linking component is a low-molecular-weight compound having two or more reactive groups. The reactive group is a functional group capable of reacting with a phenolic hydroxyl group or a carboxyl group at a terminal of the liquid crystal polymer component.

Examples of the reactive group include an epoxy group, a maleic acid anhydride group, an oxazoline group, an isocyanate group, and a carbodiimide group.

Specific examples of the cross-linking component include a bisphenol A type epoxy compound, a bisphenol F type epoxy compound, a phenol novolac type epoxy compound, a cresol novolac type epoxy compound, and a diisocyanate compound.

The content of the cross-linking component is preferably 0% to 10% by mass, more preferably 0% to 5% by mass, and particularly preferably 0% to 3% by mass with respect to the total mass of the liquid crystal polymer film.

(Compatible Component)

Examples of the compatible component include a polymer (non-reactive compatibilizer) having a moiety having high compatibility or affinity with the liquid crystal polymer and a polymer (reactive compatibilizer) having a reactive group for a phenolic hydroxyl group or a carboxyl group at the terminal of the liquid crystal polymer component.

The reactive group is as described above. Among these, as the reactive group included in the reactive compatibilizer, an epoxy group or a maleic acid anhydride group is preferable.

The non-reactive compatibilizer is further preferably a copolymer having a moiety having high compatibility or affinity with the olefin component.

The reactive compatibilizer is further preferably a copolymer having a moiety having high compatibility or affinity with the olefin component.

In particular, in a case where the liquid crystal polymer film according to the embodiment of the present invention includes the olefin component, from the viewpoint that the olefin component can be finely dispersed, the compatible component is preferably a reactive compatibilizer.

The compatible component (particularly, the reactive compatibilizer) may form a chemical bond with other components (liquid crystal polymer component and the like) in the liquid crystal polymer film.

Examples of the reactive compatibilizer include an epoxy group-containing polyolefin-based copolymer, an epoxy group-containing vinyl-based copolymer, a maleic acid anhydride-containing polyolefin-based copolymer, a maleic acid anhydride-containing vinyl copolymer, an oxazoline group-containing polyolefin-based copolymer, an oxazoline group-containing vinyl-based copolymer, and a carboxyl group-containing olefin-based copolymer. Among these, an epoxy group-containing polyolefin-based copolymer or a maleic acid anhydride-grafted polyolefin-based copolymer is preferable.

Examples of the epoxy-group containing polyolefin-based copolymer include an ethylene/glycidyl methacrylate copolymer, an ethylene/glycidyl methacrylate/vinyl acetate copolymer, an ethylene/glycidyl methacrylate/methyl acrylate copolymer, a polystyrene graft copolymer to an ethylene/glycidyl methacrylate copolymer (EGMA-g-PS), a polymethylmethacrylate graft copolymer to an ethylene/glycidyl methacrylate copolymer (EGMA-g-PMMA), and an acrylonitrile/styrene graft copolymer to an ethylene/glycidyl methacrylate copolymer (EGMA-g-AS).

Examples of a commercially available product of the epoxy group-containing polyolefin-based copolymer include Bondfast 2C and Bondfast E manufactured by Sumitomo Chemical Company; Lotadar manufactured by Arkema S.A.; and Modiper A4100 and Modiper A4400 manufactured by NOF CORPORATION.

Examples of the epoxy group-containing vinyl-based copolymer include a glycidyl methacrylate grafted polystyrene (PS-g-GMA), a glycidyl methacrylate grafted polymethyl methacrylate (PMMA-g-GMA), and a glycidyl methacrylate grafted polyacrylonitrile (PAN-g-GMA).

Examples of the maleic acid anhydride-containing polyolefin-based copolymer include a maleic acid anhydride grafted polypropylene (PP-g-MAH), a maleic acid anhydride grafted ethylene/propylene rubber (EPR-g-MAH), and a maleic acid anhydride grafted ethylene/propylene/diene rubber (EPDM-g-MAH).

Examples of a commercially available product of the maleic acid anhydride-containing polyolefin-based copolymer include Orevac G series manufactured by Arkema S.A.; and FUSABOND E series manufactured by Dow.

Examples of the maleic acid anhydride-containing vinyl copolymer include a maleic acid anhydride grafted polystyrene (PS-g-MAH), a maleic acid anhydride grafted styrene/butadiene/styrene copolymer (SBS-g-MAH), a maleic acid anhydride grafted styrene/ethylene/butene/styrene copolymer (SEBS-g-MAH), and a styrene/maleic acid anhydride copolymer and an acrylic acid ester/maleic acid anhydride copolymer.

Examples of a commercially available product of the maleic acid anhydride-containing vinyl copolymer include TUFTEC M Series (SEBS-g-MAH) manufactured by Asahi Kasei Corporation.

In addition, examples of the compatible component include oxazoline-based compatibilizers (for example, a bisoxazoline-styrene-maleic acid anhydride copolymer, a bisoxazoline-maleic acid anhydride-modified polyethylene, and a bisoxazoline-maleic acid anhydride-modified polypropylene), elastomer-based compatibilizers (for example, an aromatic resin and a petroleum resin), and ethylene glycidyl methacrylate copolymer, an ethylene maleic acid anhydride ethyl acrylate copolymer, ethylene glycidyl methacrylate-acrylonitrile styrene, acid-modified polyethylene wax, a COOH-modified polyethylene graft polymer, a COOH-modified polypropylene graft polymer, a polyethylene-polyamide graft copolymer, a polypropylene-polyamide graft copolymer, a methyl methacrylate-butadiene-styrene copolymer, acrylonitrile-butadiene rubber, a EVA-PVC-graft copolymer, a vinyl acetate-ethylene copolymer, an ethylene-α-olefin copolymer, a propylene-α-olefin copolymer, a hydrogenated styrene-isopropylene-block copolymer, and an amine-modified styrene-ethylene-butene-styrene copolymer.

In addition, as the compatible component, an ionomer resin may be used.

Examples of such an ionomer resin include an ethylene-methacrylic acid copolymer ionomer, an ethylene-acrylic acid copolymer ionomer, a propylene-methacrylic acid copolymer ionomer, a butylene-acrylic acid copolymer ionomer, a propylene-acrylic acid copolymer ionomer, an ethylene-vinyl sulfonic acid copolymer ionomer, a styrene-methacrylic acid copolymer ionomer, a sulfonized polystyrene ionomer, a fluorine-based ionomer, a telekeric polybutadiene acrylic acid ionomer, a sulfated ethylene-propylene-diene copolymer ionomer, hydrogenated polypentamer ionomer, a polypentamer ionomer, a poly(vinyl pyridium salt) ionomer, a poly(vinyltrimethylammonium salt) ionomer, a poly(vinyl benzyl phosphonium salt) ionomer, a styrene-butadiene acrylic acid copolymer ionomer, a polyurethane ionomer, a sulfated styrene-2-acrylamide-2-methyl propane sulfate ionomer, am acid-amine Ionomer, an aliphatic ionene, and an aromatic ionene.

In a case where the liquid crystal polymer film includes the compatible component, the content thereof is preferably 0.05% to 30% by mass, more preferably 0.1% to 20% by mass, and particularly preferably 0.5% to 10% by mass with respect to the total mass of the liquid crystal polymer film.

In addition, in a case where the liquid crystal polymer film includes the olefin component and the compatible component, the content of the compatible component is preferably 0.1% to 75% by mass, more preferably 1% to 70% by mass, particularly preferably 4% to 65% by mass, and still more preferably 10% to 40% by mass with respect to the content mass of the olefin component. By setting the content of the compatible component within the above-described range, the dispersion size of the olefin component can be reduced, and thus surface properties and smoothness of the surface are improved. In addition, temperature dependence of the melt viscosity can be smaller, and surface properties and smoothness of the surface are improved.

[Heat Stabilizer]

The liquid crystal polymer film according to the embodiment of the present invention also preferably includes a heat stabilizer.

Among these, it is preferable to include any of the liquid crystal polymer component, the olefin component, the compatible component, or the heat stabilizer.

In a case where the heat stabilizer is included, thermal oxidative deterioration during film formation by melt extrusion is restrained, and surface properties and smoothness of the surface of the liquid crystal polymer film are more excellent.

Examples of the heat stabilizer include phenol-based stabilizers and amine-based stabilizers having a radical scavenging action; phosphite-based stabilizers and sulfur-based stabilizers having a decomposition action of peroxide; and hybrid stabilizers having a radical scavenging action and a decomposition action of peroxide.

Examples of the phenol-based stabilizer include a hindered phenol-based stabilizer, a semi-hindered phenol-based stabilizer, and a less hindered phenol-based stabilizer.

Examples of a commercially available product of the hindered phenol-based stabilizer include ADK STAB AO-20, AO-50, AO-60, and AO-330 manufactured by ADEKA Corporation; and Irganox 259, 1035, and 1098 manufactured by BASF.

Examples of a commercially available product of the semi-hindered phenol-based stabilizer include ADK STAB AO-80 manufactured by ADEKA Corporation; and Irganox 245 manufactured by BASF.

Examples of a commercially available product of the less hindered phenol-based stabilizer include NOCRAC 300 manufactured by OUCHI SHINKO CHEMICAL INDUSTRIAL CO., LTD.; and ADK STAB AO-30 and AO-40 manufactured by ADEKA Corporation.

Examples of a commercially available product of the phosphite-based stabilizer include ADK STAB 2112, PEP-8, PEP-36, and HP-10 manufactured by ADEKA Corporation.

Examples of a commercially available product of the hybrid stabilizer include SUMILIZER GP manufactured by Sumitomo Chemical Company.

As the heat stabilizer in the present invention, from the viewpoint of obtaining a high heat stabilization effect, a hindered phenol-based stabilizer, a semi-hindered phenol-based stabilizer, or a phosphite-based stabilizer is preferable, and a hindered phenol-based stabilizer is more preferable. On the other hand, from the viewpoint of electrical characteristics, a semi-hindered phenol-based stabilizer or a phosphite-based stabilizer is more preferable.

In a case where the liquid crystal polymer film includes the heat stabilizer, the content thereof is preferably 0.0001% to 10% by mass, more preferably 0.001% to 5% by mass, and particularly preferably 0.01% to 2% by mass with respect to the total mass of the liquid crystal polymer film.

In addition, the content of the heat stabilizer is preferably 0% to 20% by mass, more preferably 0.02% to 10% by mass, and particularly preferably 0.05% to 5% by mass with respect to the mass of the olefin component included in the liquid crystal polymer film.

[Other Additives]

The liquid crystal polymer film may include other additives.

The liquid crystal polymer film may include, as a plasticizer, alkylphthalylalkyl glycolates, phosphoric acid esters, carboxylic acid esters, or polyhydric alcohols in an amount of 0% to 20% by mass with respect to the total mass of the liquid crystal polymer film.

The liquid crystal polymer film may include, as a lubricant, a fatty acid ester or a metal soap (for example, an inorganic salt of stearic acid) in an amount of 0% to 5% by mass with respect to the total mass of the liquid crystal polymer film.

The liquid crystal polymer film may include, as a reinforcing material, a matting agent, or a dielectric constant or dielectric loss tangent improving material, inorganic particles such as silica, titanium oxide, barium sulfate, talc, zirconia, alumina, silicon nitride, silicon carbide, calcium carbonate, silicate, glass bead, graphite, tungsten carbide, carbon black, clay, mica carbon fiber, glass fiber, and metal powder; or organic fine particles such as crosslinked acrylic or crosslinked styrene in an amount of 0% to 50% by mass with respect to the total mass of the liquid crystal polymer film.

The liquid crystal polymer film may include, as a UV absorber, compounds such as salicylates, benzophenones, benzotriazoles, substituted acrylonitriles, and s-triazines in an amount of 0% to 5% by mass with respect to the total mass of the liquid crystal polymer film.

[Physical properties and the like of liquid crystal polymer component]

[Thickness]

A thickness of the liquid crystal polymer film according to the embodiment of the present invention is preferably 5 to 1100 μm, more preferably 5 to 1000 μm, and particularly preferably 5 to 250 μm.

[Surface Roughness]

A surface roughness Ra of the surface of the liquid crystal polymer film according to the embodiment of the present invention is preferably less than 430 nm, more preferably less than 400 nm, particularly preferably less than 350 nm, and still more preferably less than 300 nm.

The lower limit value of the surface roughness Ra of the surface of the liquid crystal polymer film is not particularly limited, and is, for example, 10 nm or more.

In a case where the surface roughness Ra of the surface of the liquid crystal polymer film is within the above-described range, it is considered that it is easy to absorb dimensional change which occurs in the liquid crystal polymer film, and it is possible to realize more excellent surface properties and smoothness.

A method for measuring the surface roughness Ra is as shown in Example column described later.

[Dispersed Phase]

In a case where the liquid crystal polymer film according to the embodiment of the present invention includes the olefin component, it is preferable that the olefin component forms a dispersed phase in the liquid crystal polymer film.

The above-described dispersed phase corresponds to an island portion in the liquid crystal polymer film forming a so-called sea-island structure.

There is no limitation on a method of forming the sea-island structure on the liquid crystal polymer film and allowing the olefin component to exist as a dispersed phase, but for example, the contents of the liquid crystal polymer component and the olefin component in the liquid crystal polymer film may be adjusted to the above-described suitable content ranges, respectively.

From the viewpoint of more excellent smoothness of the liquid crystal polymer film, an average dispersion diameter of the dispersed phase is preferably 0.001 to 50.0 μm, more preferably 0.005 to 20.0 μm, and particularly preferably 0.01 to 10.0 μm.

A method for measuring the above-described average dispersion diameter is as shown in Example column described later.

The dispersed phase is preferably flat, and a flat surface of the flat dispersed phase is preferably substantially parallel to the liquid crystal polymer film.

In addition, from the viewpoint of reducing anisotropy of the liquid crystal polymer film, the flat surface of the flat dispersed phase is preferably substantially circular in a case of being observed from a direction perpendicular to the surface of the liquid crystal polymer film. In a case where such a dispersed phase is dispersed in the liquid crystal polymer film, it is considered that it is possible to absorb dimensional change which occurs in the liquid crystal polymer film, and it is possible to realize more excellent surface properties and smoothness.

In the liquid crystal polymer film, in a case where a length of the dispersed phase in a width direction is defined as Lx, a length of the dispersed phase in a longitudinal direction is defined as Ly, and a length of the dispersed phase in a thickness direction is defined as Lz, it is preferable that Lx, Ly, and Lz satisfy predetermined relationships described below.

A method for measuring Lx, Ly, and Lz is as shown in Example column described later.

Lx and Ly preferably satisfy Expression (1), more preferably satisfy Expression (1A), particularly preferably satisfy Expression (1B), and still more preferably satisfy Expression (1C). In a case where the dispersed phase satisfies such a condition, anisotropy of the dimensional change in the width direction and the longitudinal direction of the liquid crystal polymer film is small, and surface properties of the liquid crystal polymer film are also improved.

$$0.05 \leq Ly / Lx \leq 20. \qquad ( 1 )$$

$$0.1 \leq Ly / Lx \leq 10. \qquad ( 1 A )$$

$$0.15 \leq Ly / Lx \leq 7. \qquad ( 1 B )$$

$$0.2 \leq Ly / Lx \leq 5. \qquad ( 1 C )$$

Lx, Ly, and Lz preferably satisfy Expression (2) and/or Expression (3), more preferably satisfy Expression (2A) and/or Expression (3A), particularly preferably satisfy Expression (2B) and/or Expression (3B), still more preferably satisfy Expression (2C) and/or Expression (3C), and most preferably satisfy Expression (2D) and/or Expression (3D). In a case where the dispersed phase satisfies such a condition, anisotropy of the dimensional change in the width direction and the longitudinal direction of the liquid crystal polymer film is small, and surface properties of the liquid crystal polymer film are also improved.

$$0. 5 \leq Lz / Lx \leq 1.5 \qquad ( 2 )$$

$$0.01 0 \leq Lz / Lx \leq 1. \qquad ( 2 A )$$

$$0.01 5 \leq Lz / Lx \leq 0.70 \qquad ( 2 B )$$

$$0.02 \leq Lz / Lx \leq 0.50 \qquad ( 2 C )$$

$$0.15 \leq Lz / Lx \leq 0 \text{.50} \qquad ( 2 D )$$

$$0.005 \leq Lz / Ly \leq 1.5 \qquad ( 3 )$$

$$0.01 \leq Lz / Ly \leq 1. \qquad ( 3 A )$$

$$0.015 \leq Lz / Ly \leq 0.70 \qquad ( 3 B )$$

$$0.02 \leq Lz / Ly \leq 0.50 \qquad ( 3 C )$$

$$0.15 \leq Lz / Ly \leq 0.50 \qquad ( 3 D )$$

Lx is preferably 0.005 to 50.0 μm, more preferably 0.01 to 25.0 μm, and particularly preferably 0.05 to 10.0 μm.

Ly is preferably 0.005 to 50.0 μm, more preferably 0.01 to 25.0 μm, and particularly preferably 0.05 to 10.0 μm.

Lz is preferably 0.005 to 15.0 μm, more preferably 0.005 to 8.0 μm, and particularly preferably 0.01 to 4.0 μm.

Lx, Ly, and Lz can be appropriately adjusted by changing the manufacturing conditions of the liquid crystal polymer film.

[Viscosity]

The liquid crystal polymer film according to the embodiment of the present invention preferably has a temperature dependence of viscosity (melt viscosity) within a certain range.

More specifically, in a case where a viscosity of the liquid crystal polymer film at a temperature lower than a melting point of the liquid crystal polymer film by 30° C. is defined as η(Tm−30° C.) and a viscosity of the liquid crystal polymer film at a temperature higher than the melting point of the liquid crystal polymer film by 30° C. is defined as η(Tm+30° C.), it is preferable that Expression (4A) is satisfied, and it is more preferable that Expression (4B) is satisfied.

$$η ( T m + 30 ° C . ) / η ( Tm - 30 ° C . ) \geq 0.02 \qquad ( 4 A )$$

$$η ( Tm + 30 ° C . ) / η ( Tm - 30 ° C . ) \geq 0.05 \qquad ( 4 B )$$

The upper limit of “η(Tm+30° C.)/η(Tm−30° C.)” is not particularly limited, and is usually 1.0 or less and may be 0.50 or less.

Methods for measuring the melting point (Tm) of the liquid crystal polymer film and the viscosity are as shown in Example column described later.

[Melt Flow Rate (MFR)]

MFR of the liquid crystal polymer film is preferably 1.0 to 50.0 g/min, more preferably 3.0 to 20.0 g/min, and particularly preferably 5.0 to 10.0 g/min.

The MFR is MFR at the melting point of the liquid crystal polymer film, and a load is 5 kgf. Details of the measuring method are as shown in Example column described later.

Subsequent measurement conditions for MFR are the same unless otherwise specified.

In addition, in the liquid crystal polymer film according to the embodiment of the present invention (particularly, in a case where the liquid crystal polymer film includes the olefin component), it is preferable that MFRs of a component A and a component B obtained by a method described below satisfy the relationship represented by Expression (5), it is more preferable to satisfy the relationship represented by Expression (5A), it is particularly preferable to satisfy the relationship represented by Expression (5B), and still more preferable to satisfy the relationship represented by Expression (5C). In a case where the MFRs of the components having different compatibility characteristics satisfy the relationship as shown in Expressions, the average dispersion diameter of the dispersed phase formed in the liquid crystal polymer film can be easily adjusted within an appropriate range, and it is also easy to control the temperature dependence of the viscosity (melt viscosity) of the liquid crystal polymer film. As a result, local viscosity unevenness during manufacturing the liquid crystal polymer film is suppressed, and the effects of the present invention are more excellent.

$$0.03 \leq M F {R}^{B} / MF {R}^{A} \leq 20. \qquad ( 5 )$$

$$0.1 \leq MF {R}^{B} / MF {R}^{A} \leq 10. \qquad ( 5 A )$$

$$0.2 \leq M F {R}^{B} / MF {R}^{A} \leq 5. \qquad ( 5 B )$$

$$0.3 < M F {R}^{B} / MF {R}^{A} \leq 3.0 \qquad ( 5 C )$$

MFR^{A}: MFR of the component A at a load of 5 kgf at the melting point of the liquid crystal polymer film

MFR^{B}: MFR of the component B at a load of 5 kgf at the melting point of the liquid crystal polymer film

The value of MFR is measured according to JIS K 7210.

A method for measuring the melting point (Tm) of the liquid crystal polymer film is as shown in Example column described later.

The above-described component A and component B are obtained by performing the following steps in order from the top.

A step (step 1) of immersing the liquid crystal polymer film in dichloromethane in an amount of 1000 times a mass of the liquid crystal polymer film to produce an eluate in which a soluble component of the liquid crystal polymer film to the dichloromethane is eluted in the dichloromethane

A step (step 2) of filtrating the eluate to be separated into the component A, which is a residue, and a filtrate

A step (step 3) of dropwise adding the filtrate to ethanol to precipitate (reprecipitate) a precipitate in the ethanol

A step (step 4) of filtrating the ethanol to be separated into the component B, which is a residue, and a filtrate

In the step 1, the liquid crystal polymer film may be pulverized in order to promote the dissolution of the soluble component. In addition, in the step 1, the treatment for eluting the soluble component into dichloromethane is sufficiently performed until the amount of the soluble component eluted in the dichloromethane is constant.

It is preferable that the component A obtained as a residue in the step 2 is sufficiently dried before being subjected to the measurement of MFR.

The amount of ethanol used in the step 3 is preferably 1000 times that of the filtrate dropwise added dropwise in ethanol.

The component B obtained as a residue in the step 4 is usually the same as the precipitate precipitated in ethanol in the step 3. In addition, it is preferable that the component B obtained as a residue in the step 4 is sufficiently dried before being subjected to the measurement of MFR.

In the series of steps 1 to 4, the temperature of the liquid crystal polymer film, the temperature of dichloromethane and ethanol, and the working temperature are all set to 25° C.

It is considered that the above-described component A mainly includes a component derived from the liquid crystal polymer component in the liquid crystal polymer film.

In addition, it is considered that the component B mainly includes a component derived from other than the liquid crystal polymer component in the liquid crystal polymer film. For example, in a case where the liquid crystal polymer film includes the olefin component, it is considered that the component B mainly includes a component derived from the olefin component in the liquid crystal polymer film.

[Manufacturing Method of Liquid Crystal Polymer Film]

A manufacturing method of the liquid crystal polymer film according to the embodiment of the present invention is not particularly limited, but for example, preferably includes a pelleting step of kneading each of the above-described components to obtain pellets, and a film forming step of obtaining the liquid crystal polymer film using the pellets. In the following, the liquid crystal polymer film according to the embodiment of the present invention may be simply referred to as a “film”. Each step will be described below.

[Pelleting Step]

(Pelletization)

(1) Raw Material Form

As the liquid crystal polymer component used for the film formation, pellet-shaped, flake-shaped or powder-shaped ones can be used as they are, but for the purpose of stabilizing the film formation or uniformly dispersing an additive (meaning a component other than the liquid crystal polymer component; the same applies hereinafter), it is preferable that one or more kinds of raw materials (meaning at least one of a liquid crystal polymer component or an additive; the same applies hereinafter) are kneaded using an extruder and pelletized before use.

Hereinafter, a raw material which is a polymer, and a mixture including a polymer used for manufacturing a liquid crystal polymer film are also collectively referred to as a resin.

(2) Drying or Drying Alternative by Vent

Before pelletizing, it is preferable to dry the liquid crystal polymer component and the additive in advance. As a drying method, a method of circulating heated air having a low dew point, a method of dehumidifying by vacuum drying, and the like are used. In particular, in a case of a resin which is easily oxidized, vacuum drying or drying using an inert gas is preferable.

In addition, the drying can be substituted with a method of using a vent type extruder. The vent type extruder is available in monoaxial type and biaxial type, both of which can be used. Among these, a biaxial type is more efficient and preferred. The inside of the extruder is pelletized by a vent at less than 1 atm (preferably 0 to 0.8 atm and more preferably 0 to 0.6 atm). Such depressurization can be achieved by exhausting air from a vent or hopper provided in a kneading portion of the extruder using a vacuum pump.

(3) Raw Material Supply Method

A raw material supply method may be a method in which raw materials are mixed in advance before being made into kneaded pellets and then supplied, a method in which raw materials are separately supplied into the extruder so as to be in a fixed ratio, or a method of a combination of both.

(4) Type of Extruder

The pelletization can be produced by melting and uniformly dispersing the liquid crystal polymer component and/or additive with an extruder, cooling and solidifying, and then cutting. As the extruder, as long as a sufficient melt-kneading effect can be obtained, known monoaxial screw extruders, non-meshing different-direction rotating biaxial screw extruders, meshing different-direction rotating biaxial screw extruders, meshing co-rotating biaxial screw extruders, and the like can be used.

(5) Atmosphere During Extrusion

In a case of melt extrusion, to the extent that uniform dispersion is not hindered, it is preferable to prevent thermal and oxidative deterioration as much as possible, and it is also effective to reduce an oxygen concentration by reducing the pressure using a vacuum pump or inflowing an inert gas. These methods may be carried out alone or in combination.

(6) Rotation Speed

A rotation speed of the extruder is preferably 10 to 1000 rpm, more preferably 20 to 700 rpm, and particularly preferably 30 to 500 rpm. In a case where the rotation rate is set to the lower limit value or more, a retention time can be shortened, so that it is possible to suppress a decrease in molecular weight due to thermal deterioration and a remarkable coloration of the resin due to thermal deterioration. In addition, in a case where the rotation rate is set to the upper limit value or less, a breakage of a molecular chain due to shearing can be suppressed, so that it is possible to suppress a decrease in molecular weight and an increase in generation of crosslinked gel. It is preferable to select appropriate conditions for the rotation speed from the viewpoints of both uniform dispersibility and thermal deterioration due to extension of the retention time.

(7) Temperature

A kneading temperature is preferably set to be equal to or lower than a thermal decomposition temperature of the liquid crystal polymer component and the additive, and is preferably set to a low temperature as much as possible within a range in which a load of the extruder and a decrease in uniform kneading property are not a problem. However, in a case where the temperature is too low, the melt viscosity may increase, and conversely, a shear stress during kneading may increase, causing molecular chain breakage. Therefore, it is necessary to select an appropriate range. In addition, in order to achieve both improved dispersibility and thermal deterioration, it is also effective to melt and mix a first half part in the extruder at a relatively high temperature and lower the resin temperature in a second half part.

(8) Pressure

A kneading resin pressure during pelletization is preferably 0.05 to 30 MPa. In a case of a resin in which coloration or gel is likely to be generated due to shearing, it is preferable to apply an internal pressure of approximately 1 to 10 MPa to the inside of the extruder to fill the inside of the biaxial screw extruder with the resin raw material. As a result, the kneading can be performed more efficiently with low shear, so that uniform dispersion is promoted while suppressing thermal decomposition. An adjustment of such a pressure can be performed by adjusting Q/N (discharge amount per one rotation of screw) and/or by providing a pressure adjusting valve at the outlet of the biaxial screw kneading extruder.

(9) Shear and Screw Type

In order to uniformly disperse a plurality of types of raw materials, it is preferable to apply shear, but in a case where the shear is applied more than necessary, molecular chain breakage or gel generation may occur. Therefore, it is preferable to appropriately select a rotor segment, the number of kneading discs, or a clearance to be disposed on the screw.

A shear rate in the extruder (shear rate during pelletization) is preferably 60 to 1000 sec⁻¹, more preferably 100 to 800 sec⁻¹, and particularly preferably 200 to 500 sec⁻¹. In a case where the shear rate is set to the lower limit value or more, it is possible to suppress occurrence of melting defects of raw materials and occurrence of dispersion defects of additives. In a case where the shear rate is set to the upper limit value or less, a breakage of a molecular chain can be suppressed, and it is possible to suppress a decrease in molecular weight and an increase in generation of crosslinked gel. In addition, in a case where the shear rate during pelletization is within the above-described range, it is easy to adjust an equivalent circle diameter of the above-described island-shaped region to the above-described range.

(10) Retention Time

A retention time of the kneader can be calculated from a volume of a resin retention portion in the kneader and a discharge capacity of the polymer. An extrusion retention time in the pelletization is preferably 10 seconds to 30 minutes, more preferably 15 seconds to 10 minutes, and particularly preferably 30 seconds to 3 minutes. Deterioration of the resin and discoloration of the resin can be suppressed as long as sufficient melting can be ensured, so that it is preferable that the retention time is short.

(11) Pelletizing Method

As a pelletizing method, a method of solidifying a noodle-shaped extrusion and then cutting the extrusion is generally used, but the pelletization may be performed by an under water cut method for cutting while directly extruding from a mouthpiece into water after melting with the extruder, or a hot cut method for cutting while still hot.

(12) Pellet Size

A pellet size is preferably 1 to 300 mm² in a cross-sectional area and 1 to 30 mm in a length, and more preferably 2 to 100 mm² in a cross-sectional area and 1.5 to 10 mm in a length.

(Drying)

(1) Purpose of Drying

Before a melt film formation, it is preferable to reduce water content and volatile matter content in the pellets, and it is effective to dry the pellets. In a case where the pellets include water or volatile matter, not only appearance is deteriorated due to inclusion of bubbles in the film-forming film or decrease in haze, but also physical properties may be deteriorated due to a molecular chain breakage of the liquid crystal polymer component, or roll contamination may occur due to generation of monomers or oligomers. In addition, depending on the type of the liquid crystal polymer component used, it may be possible to suppress formation of an oxidative crosslinked substance during melt film formation by removing dissolved oxygen by the drying.

(2) Drying Method and Heating Method

As a drying method, from the viewpoints of drying efficiency and economical efficiency, a dehumidifying hot air dryer is generally used, but the drying method is not particularly limited as long as a desired moisture content can be obtained. In addition, there is no problem in selecting a more appropriate method according to characteristics of the physical properties of the liquid crystal polymer component.

Examples of a heating method include pressurized steam, heater heating, far-infrared irradiation, microwave heating, and a heat medium circulation heating method.

In order to use energy more effectively and to reduce temperature unevenness so as to perform uniform drying, it is preferable to provide a heat insulating structure in a drying equipment.

It is possible to perform stirring in order to improve drying efficiency, but pellet powder may be generated, so that the stirring may be performed properly. In addition, the drying method is not limited to one type, and a plurality of types can be combined and efficiently performed.

(3) Form of Device

The drying method has two types, a continuous method and a batch method, and in a drying method using vacuum, the batch method is preferable, while the continuous method has the advantage of excellent uniformity in a steady state, and it is necessary to use the methods depending on the application.

(4) Atmosphere and Air Volume

As for a dry atmosphere, for example, a method of blowing or depressurizing air having a low dew point or inert gas having a low dew point is used. The dew point of the air is preferably 0° C. to −60° C., more preferably 10° C. to −55° C., and particularly preferably −20° C. to −50° C. Setting a low dew point atmosphere is preferable from the viewpoint of reducing the volatile matter content contained in the pellets, but is disadvantageous from the viewpoint of economical efficiency, and an appropriate range may be selected. In a case where the raw material is damaged by oxygen, it is also effective to use an inert gas to reduce oxygen partial pressure.

An air volume required per one ton of the liquid crystal polymer component is preferably 20 to 2000 m³/hour, more preferably 50 to 1000 m³/hour, and particularly preferably 100 to 500 m³/hour. In a case where the drying air volume is the lower limit value or more, the drying efficiency is improved. In a case where the drying air volume is the upper limit value or less, it is economically preferred.

(5) Temperature and Time

In a case where the raw material is in an amorphous state, a drying temperature is preferably {Glass transition temperature (Tg) (° C.)+80° C.} to {Tg (° C.)−80° C.}, more preferably {Tg (° C.)+40° C.} to {Tg (° C.)−40° C.}, and particularly preferably {Tg (° C.)+20° C.} to {Tg (° C.)−20° C.}.

In a case where the drying temperature is the upper limit value or less, blocking due to softening of the resin can be suppressed, so that transportability is excellent. On the other hand, in a case where the drying temperature is the lower limit value or more, the drying efficiency can be improved, and the moisture content can be set to a desired value.

In addition, in a case of a crystalline resin, the resin can be dried without melting in a case of {Melting point (Tm) (° C.)−30° C.} or lower. Excessive temperatures may result in coloration and/or change in molecular weight (generally decreased, but in some cases, increased). In addition, since the drying efficiency is low even in a case where the temperature is too low, it is necessary to select appropriate conditions. As a guide, {Tm (° C.)−250° C.} to {Tm (° C.)−50° C.} is preferable.

A drying time is preferably 15 minutes or more, more preferably 1 hour or more, and particularly preferably 2 hours or more. Even in a case of being dried for more than 50 hours, an effect of further reducing the water content is small and there is a concern about thermal deterioration of the resin, so that it is not necessary to lengthen the drying time unnecessarily.

(6) Moisture Content

A moisture content of the pellets is preferably 1.0% by mass or less, more preferably 0.1% by mass or less, and particularly preferably 0.01% by mass or less.

(7) Transportation Method

In order to prevent water re-adsorption to the dried pellets, it is preferable to use dry air or nitrogen for transporting the pellets. In addition, in order to stabilize the extrusion, it is also effective to supply high temperature pellets at a constant temperature to the extruder, and it is also common to use heated dry air to maintain the heated state.

[Film Forming Step]

(Manufacturing Device) Hereinafter, an example of each equipment constituting the manufacturing device will be described.

(Extruder, Screw, and Barrel)

(1) Extruder Structure

The raw materials (pellets) are supplied into a cylinder through a supply port of the extruder. The inside of the cylinder is composed of a supply unit for quantitatively transporting the supplied raw materials in order from the supply port side, a compression unit for melt-kneading and compressing the raw materials, and a measuring unit for measuring the melt-kneaded and compressed raw materials. A heating and cooling device divided into a plurality of parts is provided on an outer peripheral portion of the cylinder, so that each zone in the cylinder can be controlled to a desired temperature. A band heater or a sheathed wire aluminum cast heater is usually used for heating the cylinder, but a heat medium circulation heating method can also be used. In addition, although air cooling with a blower is generally used for cooling, there is also a method of flowing water or oil through a pipe wound around the outer circumference of the cylinder.

Further, it is preferable to cool the supply port portion in order to prevent the pellets from being heated and fused and to prevent heat transfer for protecting a screw drive equipment.

It is necessary to use a material for an inner wall surface of the cylinder, which has excellent heat resistance, abrasion resistance, and corrosion resistance and can secure friction with the resin. Generally, nitriding steel in which an inner surface is nitrided is used, but chrome molybdenum steel, nickel chrome molybdenum steel, and stainless steel can also be nitrided and used.

Especially for applications where abrasion resistance and corrosion resistance are required, it is effective to use a bimetallic cylinder with a corrosion-resistant and abrasion-resistant material alloy, such as nickel, cobalt, chrome, and tungsten, lined on the inner wall surface of the cylinder by centrifugal casting, and form a ceramic sprayed coating.

In addition, although the cylinder usually has a smooth inner surface, an axial groove (square groove, semicircular groove, helical groove, and the like) may be provided on an interior wall of the cylinder for the purpose of increasing the extrusion amount. However, since the groove in the cylinder causes polymer retention in the extruder, it is necessary to be careful in a case of using the cylinder having a groove in applications where foreign matter levels are strict.

(2) Type of Extruder

Generally used extruders are roughly classified into monoaxial (single-screw) and biaxial type, and monoaxial extruders are widely used. Biaxial (multiaxial) screws are roughly classified into meshing type and non-meshing type, and rotation directions are also divided into the same direction and different directions. The meshing type has a higher kneading effect than the non-meshing type, and is often used. In addition, the different-direction rotating screw has a higher kneading effect than the co-rotating type, but the co-rotating type has a self-cleaning effect, and thus is effective in preventing retention in the extruder. Furthermore, there are parallel and oblique crossing in the axial direction, and there is also a conical type shape used in a case of applying strong shear. In the biaxial extruder, by properly disposing a vent port, undried raw materials (pellets, powder, flakes, and the like), selvage of a film, produced during film formation, and the like can be used as they are, so the biaxial extruder is widely used. However, even in a case of the monoaxial extruder, it is possible to remove volatile components by properly disposing a vent port. It is important to select the extruder used for film formation according to the required extrusion performance (extrusion stability, kneading property, retention prevention, heat history) and the characteristics of the extruder.

In the extruder, it is common to use monoaxial and biaxial (multiaxial) individually, but it is also common to use them in combination by taking advantage of their respective characteristics. For example, a combination of a biaxial extruder which can use an undried raw material and a monoaxial extruder having good meterability is widely used for forming a film of polyester (PET) resin.

(3) Screw Type and Structure

Here, an example of a screw for a monoaxial extruder is shown. As a shape of the screw generally used, a full flight screw provided with a single spiral flight of equal pitch is often used. In addition, a double flight screw capable of stabilizing extrudability by separating a solid-liquid phase of the resin in the melting process by using two flights is often used. Further, in order to improve kneading property in the extruder, it is common to combine mixing elements such as Maddock, Dulmage, and a barrier. Furthermore, in order to enhance the kneading effect, a screw having a polygonal cross section, or a screw having a distribution hole for imparting a distribution function in order to reduce temperature unevenness in the extruder is also used.

As a material used for the screw, it is necessary to use a material having excellent heat resistance, abrasion resistance, and corrosion resistance and capable of ensuring friction with the resin, as in the case of the cylinder. General examples thereof include nitrided steel, chrome molybdenum steel, nickel chrome molybdenum steel, and stainless steel. Generally, a screw is manufactured by grinding the above-described steel material and performing nitriding treatment and/or plating treatment such as HCr, but a screw surface may be subjected to special surface treatment such as TiN, CrN, or Ti coating by physical vapor deposition (PVD) or chemical vapor deposition (CVD).

Diameter and Groove Depth

A preferred screw diameter varies depending on the target extrusion amount per unit time, but is preferably 10 to 300 mm, more preferably 20 to 250 mm, and particularly preferably 30 to 150 mm. A groove depth of a screw feed portion is preferably 0.05 to 0.20 times, more preferably 0.07 to 0.18 times, and particularly preferably 0.08 to 0.17 times the screw diameter. A flight pitch is generally the same as the screw diameter, but a shorter one may be used to increase the uniformity of melting, or a longer one may be used to increase the extrusion rate. In addition, a flight groove width is preferably 0.05 to 0.25 of the screw flight pitch, and generally approximately 0.1 is often used from the viewpoint of friction between the screw and the barrel and reduction of the retention portion. A clearance between the flight and the barrel is also 0.001 to 0.005 times the screw diameter, but 0.0015 to 0.004 times is preferable from the viewpoint of friction between the barrels and reduction of the retention portion.

Compression Rate

In addition, a screw compression ratio of the extruder is preferably 1.6 to 4.5. Here, the screw compression ratio is expressed as a volume ratio between the supply unit and the measuring unit, that is, (Volume per unit length of supply unit)+(Volume per unit length of measuring unit), and is calculated from using the outer diameter of the screw shaft of the supply unit, the outer diameter of the screw shaft of the measuring unit, the groove diameter of the supply unit, and the groove diameter of the measuring unit. In a case where the screw compression ratio is 1.6 or more, sufficient melt-kneading property can be obtained, the generation of undissolved portions can be suppressed, undissolved foreign matters are less likely to remain on the film after manufacturing, and the mixing of air bubbles can be suppressed by the defoaming effect. On the contrary, in a case where the screw compression ratio is 4.5 or less, it is possible to prevent excessive shear stress from being applied. Specifically, it is possible to suppress a decrease in the mechanical strength of the film due to molecular chain breakage, a superheat coloring phenomenon due to shear heat generation, and a decrease in foreign matter level due to gel generation. Therefore, the appropriate screw compression ratio is preferably 1.6 to 4.5, more preferably 1.7 to 4.2, and particularly preferably 1.8 to 4.0.

L/D

L/D is a ratio of the cylinder length to the cylinder inner diameter. In a case where the L/D is 20 or more, melting and kneading are sufficient, and the generation of undissolved foreign matter in the film after manufacturing can be suppressed as in the case where the compression ratio is appropriate. In addition, in a case where the L/D is 70 or less, the retention time of the liquid crystal polymer component in the extruder is shortened, so that the deterioration of the resin can be suppressed. Further, in a case where the retention time can be shortened, the decrease in the mechanical strength of the film caused by the decrease in the molecular weight due to the breakage of the molecular chain can be suppressed. Therefore, the L/D is preferably in a range of 20 to 70, more preferably in a range of 22 to 65, and particularly preferably in a range of 24 to 50.

Screw Proportion

A length of the extruder supply unit is preferably 20% to 60%, more preferably 30% to 50% of an effective screw length (total length of the supply unit, compression unit, and measuring unit). A length of the extruder compression unit is preferably 5% to 50% of the effective screw length, is preferably 5% to 40% in a case where the target of kneading is a crystalline resin, and preferably 10% to 50% in a case where the target of kneading is an amorphous resin. The measuring unit preferably has a 20% to 60% length of the effective screw length, and more preferably 30% to 50% length. It is also common practice to divide the measuring portion into a plurality of parts and arrange a mixing element between them to improve the kneading property.

Q/N

A discharge amount (Q/N) of the extruder is preferably 50% to 99%, more preferably 60% to 95%, and particularly preferably 70% to 90% of a theoretical maximum discharge amount (Q/N)_{MAX}. Q indicates a discharge amount [cm³/min], N indicates a screw rotation speed [rpm], and (Q/N) indicates a discharge amount per screw rotation. In a case where the discharge amount (Q/N) is 50% or more of the theoretical maximum discharge amount (Q/N)_{MAX}, the retention time in the extruder can be shortened and the progress of thermal deterioration inside the extruder can be suppressed. In addition, in a case of being 99% or less, a back pressure is sufficient, so that the kneading property is improved, the melting uniformity is improved, and the stability of the extrusion pressure is also good.

It is preferable to select the optimum screw dimension in consideration of the crystallinity of the resin, the melt viscous property, the heat stability, the extrusion stability, and the uniformity of the melt plasticization.

(4) Extrusion Conditions

Drying of Raw Materials

In the melt plasticization step of pellets using the extruder, as in the pelleting step, it is preferable to reduce water content and volatile matter content in the pellets, and it is effective to dry the pellets.

Raw Material Supply Method

In a case where there are multiple types of raw materials (pellets) input from the extruder supply port, the raw materials may be mixed in advance (premix method), may be separately supplied into the extruder in a fixed ratio, or may be a combination of both. In addition, in order to stabilize the extrusion, it is generally practiced to reduce the fluctuation of the temperature and the bulk specific density of the raw material charged from the supply port. Further, from the viewpoint of thermoplastic efficiency, a raw material temperature is preferably high as long as it does not adhere to the supply port and block, and in a case where the raw material is in an amorphous state, the raw material temperature is preferably {Glass transition temperature (Tg) (° C.)−150° C.} to {Tg (° C.)−1° C.}, and in a case where the raw material is a crystalline resin, the raw material temperature is preferably {Melting point (Tm) (° C.)−150° C.} to {Tm (° C.)−1° C.}, and the raw material is heated or kept warm. Further, from the viewpoint of thermoplastic efficiency, the bulk specific gravity of the raw material is preferably 0.3 times or more, and particularly preferably 0.4 times or more in a case of a molten state. In a case where the bulk specific density of the raw material is less than 0.3 times the specific gravity in the molten state, it is also preferable to perform a processing treatment such as compressing the raw material into pseudo-pellets.

Atmosphere During Extrusion

As for the atmosphere during melt extrusion, it is necessary to prevent heat and oxidative deterioration as much as possible within the range that does not hinder uniform dispersion as in the pelleting step. It is also effective to inject an inert gas (nitrogen or the like), reduce the oxygen concentration in the extruder by using a vacuum hopper, and provide a vent port in the extruder to reduce the pressure by a vacuum pump. These depressurization and injection of the inert gas may be carried out independently or in combination.

Rotation Speed

A rotation speed of the extruder is preferably 5 to 300 rpm, more preferably 10 to 200 rpm, and particularly preferably 15 to 100 rpm. In a case where the rotation rate is set to the lower limit value or more, the retention time is shortened, the decrease in molecular weight can be suppressed due to thermal deterioration, and discoloration can be suppressed. In a case where the rotation rate is set to the upper limit value or less, a breakage of a molecular chain due to shearing can be suppressed, and it is possible to suppress a decrease in molecular weight and an increase in generation of crosslinked gel. It is preferable to select appropriate conditions for the rotation speed from the viewpoints of both uniform dispersibility and thermal deterioration due to extension of the retention time.

Temperature

A barrel temperature (supply unit temperature T₁° C., compression unit temperature T₂° C., and measuring unit temperature T₃° C.) is generally determined by the following method. In a case where the pellets are melt-plasticized at a target temperature T° C. by the extruder, the measuring unit temperature T₃ is set to T±20° C. in consideration of the shear calorific value. In this case, T₂ is set within a range of T₃±20° C. in consideration of extrusion stability and thermal decomposability of the resin. Generally, T₁ is set to {T₂ (° C.)−5° C.} to {T₂ (° C.)−150° C.}, and the optimum value of T₁ is selected from the viewpoint of ensuring friction between the resin and the barrel, which is the driving force (feed force) for feeding the resin, and preheating at the feed portion. In a case of a normal extruder, it is possible to subdivide each zone of Ti to T₃ and set the temperature, and by setting such that the temperature change between each zone is gentle, it is possible to make it more stable. In this case, T is preferably set to be equal to or lower than the thermal deterioration temperature of the resin, and in a case where the thermal deterioration temperature is exceeded due to the shear heat generation of the extruder, it is generally performed to positively cool and remove the shear heat generation. In addition, in order to achieve both improved dispersibility and thermal deterioration, it is also effective to melt and mix a first half part in the extruder at a relatively high temperature and lower the resin temperature in a second half part.

Screw Temperature Control

Controlling the temperature of the screw is also performed to stabilize the extrusion. As a temperature control method, it is common to flow water or a medium inside the screw, and in some cases, a heater may be built the inside of the screw to heat the screw. The temperature range is generally controlled in the screw supply unit, but in some cases, the compression unit or the measuring unit may also be controlled, and the temperature may be controlled to a different temperature in each zone.

Pressure

A resin pressure in the extruder is generally 1 to 50 MPa, and from the viewpoint of extrusion stability and melt uniformity, preferably 2 to 30 MPa and more preferably 3 to 20 MPa. In a case where the pressure in the extruder is 1 MPa or more, the filling rate of the melting in the extruder is sufficient, so that the destabilization of the extrusion pressure and the generation of foreign matter due to the generation of retention portions can be suppressed. In addition, in a case where the pressure in the extruder is 50 MPa or less, it is possible to suppress the excessive shear stress received in the extruder, so that thermal decomposition due to an increase in the resin temperature can be suppressed.

Retention Time

The retention time in the extruder (retention time during film formation) can be calculated from the volume of the extruder portion and the discharge capacity of the polymer, as in the pelleting step. The retention time is preferably 10 seconds to 60 minutes, more preferably 15 seconds to 45 minutes, and most preferably 30 seconds to 30 minutes. In a case where the retention time is 10 seconds or more, the melt plasticization and the dispersion of the additive are sufficient. In a case where the retention time is 30 minutes or less, it is preferable in that resin deterioration and discoloration of the resin can be suppressed.

(Filtration)

Type, Installation Purpose, and Structure

It is generally used to provide a filtration equipment at the outlet of the extruder in order to prevent damage to the gear pump due to foreign matter included in the raw material and to extend the life of the filter having a fine pore size installed downstream of the extruder. It is preferable to perform so-called breaker plate type filtration in which a mesh-shaped filtering medium is used in combination with a reinforcing plate having a high opening ratio and having strength.

Mesh Size and Filtration Area

A mesh size is preferably 40 to 800 mesh, more preferably 60 to 700 mesh, and particularly preferably 100 to 600 mesh. In a case where the mesh size is 40 mesh or more, it is possible to sufficiently suppress foreign matter from passing through the mesh. In addition, in a case where the mesh is 800 mesh or less, the improvement of the filtration pressure increase speed can be suppressed and the mesh replacement frequency can be reduced. Further, from the viewpoint of filtration accuracy and strength maintenance, it is generally used to superimpose a plurality of types of filter meshes having different mesh sizes. Further, since the filtration opening area can be widened and the strength of the mesh can be maintained, it is also used to reinforce the filter mesh by using a breaker plate. An opening ratio of the breaker plate used is generally 30% to 80% from the viewpoints of filtration efficiency and strength.

In addition, a screen changer is often used with the same diameter as the barrel diameter of the extruder, but in order to increase the filtration area, it is also commonly used to use a larger diameter filter mesh using a tapered pipe, or to use a plurality of breaker plates by branching a flow channel. The filtration area is preferably selected with a flow rate of 0.05 to 5 g/cm² per second as a guide, more preferably 0.1 to 3 g/cm², and particularly preferably 0.2 to 2 g/cm².

By capturing foreign matter, the filter is clogged and the filter pressure rises. In that case, it is necessary to stop the extruder and replace the filter, but a type in which the filter can be replaced while continuing extrusion can also be used. In addition, as a measure against an increase in the filtration pressure due to the capture of foreign matter, a substance having a function of lowering the filtration pressure by cleaning and removing the foreign matter trapped in the filter by reversing the flow channel of the polymer can also be used.

(Microfiltration)

Type, Installation Purpose, and Structure

In order to perform foreign matter filtration with higher accuracy, it is preferable to provide a precision filter device with high filtration accuracy before extrusion from the die. It is preferable that the filtration accuracy of the filtering medium of the filter is high, but in consideration of the pressure resistance of the filtering medium and the suppression of the increase in the filter pressure due to clogging of the filtering medium, the filtration accuracy is preferably 3 to 30 μm, more preferably 3 to 20 and particularly preferably 3 to 10 μm. The microfiltration device is usually provided at one place, but multi-stage filtration performed at a plurality of places in series and/or in parallel may be performed. Since the filter to be used has a large filtration area and high pressure resistance, it is preferable to provide a filtration device incorporating a leaf type disc filter. The leaf type disc filter can adjust the number of loaded sheets in order to secure the withstand voltage and the suitability of the filter life.

The required filtration area varies depending on the melt viscosity of the resin to be filtered, but is preferably 5 to 100 g·cm⁻²·h⁻¹, more preferably 10 to 75 g·cm⁻²·h⁻¹, and particularly preferably 15 to 50 g·cm⁻²·h⁻¹. Increasing the filtration area is advantageous from the viewpoint of increasing the filter pressure, but it increases the retention time inside the filter and causes the generation of deteriorated foreign matter, so it is necessary to select appropriate conditions.

As a type of the filtering medium, it is preferable to use a steel material from the viewpoint of being used under high temperature and high pressure, and it is more preferable to use stainless steel or steel among the steel materials, and it is particularly preferable to use stainless steel from the viewpoint of corrosion.

As a configuration of the filtering medium, in addition to the knitted wire rod, for example, a sintered filtering medium formed by sintering metal filaments or metal powder is also used. In addition, it is common to use a filter with a single diameter wire, but in order to improve the filter life or filtration accuracy, those having different wire diameters in the thickness direction of the filter may be laminated, or a filtering medium having a continuously changing wire diameter may be used.

In addition, a thickness of the filter is preferably thick from the viewpoint of filtration accuracy, while it is preferably thin from the viewpoint of increasing the filter pressure. Therefore, the thickness of the filter is preferably 200 μm to 3 mm, more preferably 300 μm to 2 mm, and particularly preferably 400 μm to 1.5 mm as a range in which compatibility conditions are possible.

A filter porosity is preferably 50% or more and more preferably 70% or more. In a case of being 50% or more, the pressure loss is low and the clogging is small, so that the operation can be performed for a long time. The filter porosity is preferably 90% or less. In a case of being 90% or less, it is possible to suppress the filtering medium from being crushed in a case where the filter pressure rises, so that the rise in the filter pressure can be suppressed.

It is preferable to appropriately select the filtration accuracy of the filtering medium, the wire diameter of the filtering medium, the porosity of the filtering medium, and the thickness of the filtering medium according to the melt viscosity of the object to be filtered and the filtration flow rate.

(Connection Pipe and the Like)

It is necessary that a pipe (adapter pipe, switching valve, mixing device, and the like) which connects each part of a film forming apparatus has excellent corrosion resistance and heat resistance, similar to the barrel and screw of the extruder, and usually, chrome molybdenum steel, nickel chrome molybdenum steel, or stainless steel is used. In addition, in order to improve the corrosion resistance, a surface of a polymer flow channel is plated with HCr, Ni, or the like.

Further, in order to prevent retention inside the pipe, the surface roughness inside the pipe is preferably Ra=200 nm or less, and more preferably Ra=150 nm or less.

Further, it is preferable that the pipe diameter is large from the viewpoint of reducing pressure loss, but on the other hand, retention is likely to occur due to a decrease in the flow velocity of the pipe portion. Therefore, it is necessary to select an appropriate pipe diameter, but 5 to 200 Kg·cm⁻²·h⁻¹ is preferable, 10 to 150 Kg·cm⁻²·h⁻¹ is more preferable, and 15 to 100 Kg·cm⁻²·h⁻¹ is particularly preferable.

In order to stabilize the extrusion pressure of the liquid crystal polymer component having a high temperature dependence of the melt viscosity, it is preferable to minimize the temperature fluctuation of the piping portion as well. Generally, a band heater having a low equipment cost is often used for heating the pipe, but an aluminum cast heater having a small temperature fluctuation or a method using a heat medium circulation is more preferable. In addition, it is preferable to divide the pipe into a plurality of pipes as in the case of the cylinder barrel and control each zone individually from the viewpoint of reducing temperature unevenness. Further, as for temperature control, proportional-integral-differential (PID) controller is generally used. Further, it is preferable to use a combination of a method of variably controlling the heater output by using an AC power regulator.

Further, for uniformizing the film, it is also effective to make the raw material temperature and the composition uniform by installing a mixing device in the flow channel of the extruder. Examples of the mixing device include a spiral type or a stator type static mixer, a dynamic mixer, and the like, and the spiral type static mixer is effective for homogenizing a high-viscosity polymer. By using an n-stage static mixer, homogenization is divided into 2n, so that as n is larger, uniformization is further promoted. On the other hand, there is also the problem of pressure loss or the generation of retention portions, so it is necessary to select according to the required uniformity. For homogenization of the film, 5 to 20 steps are preferable, 7 to 15 steps are more preferable, and it is preferable to extrude the film from the die immediately after homogenization with a static mixer to form a film.

In addition, it is also possible to install a bleed valve in the extruder flow channel which can discharge the polymer that has deteriorated inside the extruder so that it does not pass through the filter and die. However, since a switching portion is stagnant and causes foreign matter to be generated, the switching valve portion is required to have severe processing accuracy.

(Gear Pump)

In order to improve thickness accuracy, it is preferable to reduce the fluctuation of the discharge amount. By providing a gear pump between the extruder and the die and supplying a certain amount of resin from the gear pump, the thickness accuracy can be improved. The gear pump is housed in a state where a pair of gears consisting of a drive gear and a driven gear are meshed with each other, and by driving the drive gear and engaging and rotating both gears, the molten resin is sucked into the cavity from the suction port formed in the housing, and a certain amount of the resin is discharged from the outlet also formed in the housing. Even in a case where the resin pressure at a tip part of the extruder fluctuates slightly, the fluctuation is absorbed by using the gear pump, the fluctuation of the resin pressure downstream of the film forming apparatus is very small, and the thickness fluctuation is improved. By using the gear pump, the pressure fluctuation on a secondary side of the gear pump can be reduced to ⅕ or less of a primary side of the gear pump, and the resin pressure fluctuation range can be set to within ±1%. Other merits are that filtration by a filter is possible without increasing the pressure at the tip part of the screw, so that it can be expected to prevent the resin temperature from rising, improve the transportation efficiency, and shorten the retention time in the extruder. In addition, it is possible to prevent the amount of resin supplied from the screw from fluctuating with time due to an increase in the filter pressure of the filter.

Type and Size

Normally, a two-gear type is used, in which quantification is performed by the meshing rotation of two gears. In addition, in a case where the pulsation caused by the gears of the gear is a problem, it is generally used to use a three-gear type to interfere with each other's pulsation to reduce the pulsation. A size of the gear pump to be used is generally selected to have a capacity such that the rotation speed is 5 to 50 rpm under the extrusion conditions, preferably 7 to 45 rpm, and more preferably 8 to 40 rpm.

By selecting the size of the gear pump in which the rotation speed is within the above-described range, it is possible to suppress the resin temperature rise due to shear heat generation and suppress the resin deterioration due to the retention inside the gear pump.

In addition, since the gear pump is constantly worn by the meshing of gears, it is required to use a material having excellent abrasion resistance, and it is preferable to use a abrasion-resistant material same as the screw or the barrel.

Countermeasures for Retention Portions

Poor flow of the bearing circulation polymer of the gear pump may cause problems such as poor sealing by the polymer in the driving unit and the bearing unit, resulting in large fluctuations in weighing and liquid feed extrusion pressure. Therefore, it is necessary to design the gear pump (especially clearance) according to the melt viscosity of the liquid crystal polymer component. In addition, in some cases, the retention portion of the gear pump causes deterioration of the liquid crystal polymer component, so a structure with as little stagnant as possible is preferable. Further, a method of preventing a retained polymer from being mixed in the film by discharging the retained polymer of the bearing unit to the outside of the gear pump is also used. Further, in a case where the shear calorific value in the gear pump is large and the resin temperature rises, it is also effective to cool the gear pump by air cooling and/or circulating a cooling medium.

Operating Conditions

In a case where a difference between a primary pressure (input pressure) and a secondary pressure (output pressure) is too large in the gear pump, the load on the gear pump is large and the shear heat generation is large. Therefore, the differential pressure during operation is preferably 20 MPa or less, more preferably 15 MPa or less, and particularly preferably 10 MPa or less. It is also effective to control the screw rotation of the extruder or use a pressure control valve to keep the primary pressure of the gear pump constant in order to make the film thickness uniform.

(Die)

Type, Structure, and Material

The molten resin from which foreign matters have been removed by filtration and in which the temperature has been made uniform by a mixer is continuously sent to the die. Any type of commonly used T die, fishtail die, or hanger coat die can be used as long as the die is designed so that the retention of molten resin is small. Among these, the hanger coat die is preferable in terms of thickness uniformity and less retention.

A clearance of the T-die outlet portion is preferably 1 to 20 times, more preferably 1.5 to 15 times, and particularly preferably 2.0 to 10 times the film thickness. In a case where the lip clearance is 1 times or more of the film thickness, an increase in the internal pressure of the die can be suppressed, so that the film thickness can be easily controlled, and a sheet having a good surface shape can be obtained by film formation. In addition, in a case where the lip clearance is 20 times or less of the film thickness, it is possible to prevent the draft ratio from becoming too large, so that the sheet thickness accuracy is good.

The thickness of the film is generally adjusted by adjusting the clearance of the base at the tip part of the die, and it is preferable to use a flexible lip from the viewpoint of thickness accuracy. In addition, the thickness may be adjusted using a chalk bar.

The clearance adjustment of the base can be changed by using the adjustment bolt at the die outlet portion. The adjusting bolts are preferably arranged at intervals of 15 to 50 mm, more preferably at intervals of 35 mm or less, and preferably at intervals of 25 mm or less. In a case where the interval is 50 mm or less, the occurrence of thickness unevenness between the adjusting bolts can be suppressed. In a case where the interval is 15 mm or more, stiffness of the adjusting bolt is sufficient, so that the fluctuation of the internal pressure of the die can be suppressed and the fluctuation of the film thickness can be suppressed. In addition, an inner wall surface of the die is preferably smooth from the viewpoint of wall retention, and for example, the surface smoothness can be improved by polishing. In some cases, after the inner wall surface is plated, the smoothness is increased by polishing, or peelability from the polymer is improved by vapor deposition.

In addition, it is preferable that the flow rate of the polymer discharged from the die is uniform in the width direction of the die. Therefore, it is preferable to change the manifold shape of the die to be used depending on the melt viscosity shear rate dependence of the liquid crystal polymer component to be used.

In addition, it is preferable that the temperature of the polymer discharged from the die is also uniform in the width direction of the die. Therefore, it is preferable to make the temperature uniform by raising the set temperature of the die end part having a large heat dissipation of the die or by taking measures such as suppressing the heat dissipation of the die end part.

In addition, since insufficient processing accuracy of the die or foreign matter adhering to the die outlet portion causes die streaks to occur, which causes a significant deterioration in the quality of the film, the die lip portion is preferably smooth, and a surface roughness Ra of the die lip portion is preferably 0.05 μm or less, more preferably 0.03 μm or less, and particularly preferably 0.02 μm or less. A curvature radius R of the die lip edge portion is preferably 100 μm or less, more preferably 70 μM or less, and particularly preferably 50 μm or less. In addition, by spraying ceramic, one processed into a sharp edge with R=20 μm or less can also be used.

To reduce the thickness variation in long-term continuous production, an automatic thickness adjustment die that measures the film thickness downstream, calculates the thickness deviation, and feeds back the result to the thickness adjustment of the die is also effective.

The area between the die and the roll landing point of the polymer is called an air gap, and it is preferable that the air gap is short in order to improve the thickness accuracy and stabilize the film formation by reducing the neck-in amount (increasing the edge thickness by reducing the film width). By making the angle of the tip part of the die sharp or reducing the thickness of the die, it is possible to prevent interference between the roll and the die and shorten the air gap, but on the other hand, the stiffness of the die may decrease, and the pressure of the resin may cause the central portion of the die to open, resulting in a decrease in thickness accuracy. Therefore, it is preferable to select conditions which can achieve both the stiffness of the die and the shortening of the air gap.

Multi-Layer Film Formation

A single-layer film forming apparatus having a low equipment cost is generally used for manufacturing a film. In addition, a multi-layer film forming apparatus may be used to provide a functional layer such as a surface protective layer, a pressure-sensitive adhesive layer, an easy adhesion layer, and/or an antistatic layer on the outer layer. Specific examples thereof include a method of performing multi-layering using a multi-layer feed block and a method of using a multi-manifold die. Generally, it is preferable to laminate the functional layer thinly on the surface layer, but the layer ratio is not particularly limited.

The retention time (retention time from passing through the extruder to discharging the die) from the pellets entering the extruder through the supply port and exiting from the supply unit (for example, die) is preferably 1 to 30 minutes, more preferably 2 to 20 minutes, and particularly preferably 3 to 10 minutes. From the viewpoint of thermal deterioration of the polymer, it is preferable to select equipment having a short retention time. However, in order to reduce the volume inside the extruder, for example, in a case where the capacity of the filtration filter is too small, the filter life may be shortened and the replacement frequency may increase. In addition, making the pipe diameter too small may also increase the pressure loss. For this reason, it is preferable to select equipment of appropriate size.

In addition, by setting the retention time to 30 minutes or less, it is easy to adjust the diameter corresponding to the maximum equivalent circle diameter of the bright portion to the above-described range.

(Cast)

The film forming step preferably includes a step of supplying the melted liquid crystal polymer component from the supply unit and a step of landing the melted liquid crystal polymer component on a cast roll to form a film. The melted liquid crystal polymer component may be cooled and solidified and wound as it is as a film, or it may be passed between a pair of pressing compression surfaces and continuously pressed to form a film.

In this case, there is no particular limitation on the unit for supplying the liquid crystal polymer component (melting) in a molten state. For example, as a specific unit for supplying the melting, an extruder which melts the liquid crystal polymer component and extrudes it into a film may be used, an extruder and a die may be used, or the liquid crystal polymer component may be once solidified into a film and then melted by a heating unit to form a melt, which may be supplied to the film forming step.

In a case where the molten resin extruded from the die into a sheet is pressed by a device having a pair of pressing compression surfaces, not only can the surface morphology of the compression surface be transferred to the film, but aligning properties can be controlled by imparting elongation deformation to the composition containing the liquid crystal polymer component.

Film Forming Method and Type

Among the methods for forming a molten raw material into a film, it is preferable to pass between two rolls (for example, a touch roll and a chill roll) from the viewpoint that a high pinching pressure can be applied and the film surface is excellent. In the present specification, in a case where a plurality of cast rolls for transporting the melt are provided, the cast roll closest to the most upstream liquid crystal polymer component supply unit (for example, die) is referred to as a chill roll. In addition, a method of pressing metal belts with each other or a method of combining a roll and a metal belt can also be used. In some cases, in order to improve adhesiveness with rolls or metal belts, a film forming method such as a static electricity application method, an air knife method, an air chamber method, and a vacuum nozzle method can be used in combination on a cast drum.

In addition, in a case of obtaining a film having a multi-layer structure, it is preferable to obtain the film by pressing the molten polymer extruded from the die in multiple layers, but it is also possible to obtain a multi-layer film by introducing a single-layer film into a pressing portion in the same manner as a melt-laminated film. Further, in this case, by changing the circumferential speed difference or the orientation axis direction of the pressing portion, films having different inclined structures in the thickness direction can be obtained, and by performing this step several times, it is possible to obtain films having three or more layers.

Furthermore, the touch roll may be periodically vibrated in the TD direction in a case of pinching to give deformation.

Roll Type and Material

As the cast roll, from the viewpoint of surface roughness, uniformity of pressing in a case of pinching, and uniformity of roll temperature, a metal roll having a stiffness is preferable. “Having stiffness” is not determined only by the material of the compression surface, but is determined by considering the ratio between the thickness of a rigid material used for the surface portion and the thickness of the structure supporting the surface portion. For example, in a case where the surface portion is driven by a cylindrical support roll, it means that the ratio of the thickness of the outer cylinder of the rigid material/the diameter of the support roll is, for example, approximately 1/80 or more.

Carbon steel and stainless steel are generally used as the material for the rigid metal roll. In addition, chrome molybdenum steel, nickel chrome molybdenum steel, cast iron, and the like can also be used. Further, in order to modify the surface properties such as film peelability, plating treatment such as chromium or nickel, or processing such as ceramic spraying may be performed. In a case where a metal belt is used, the thickness of the belt is preferably 0.5 mm or more, more preferably 1 mm or more, and particularly preferably 2 mm or more in order to apply the necessary pinching pressure. In addition, in a case of using a rubber roll or a roll which combines a rubber roll and a metal sleeve, Since the hardness of the roll is low and the length of the pinching portion is long, the effective pinching pressure may not be high even in a case where a high linear pressure is applied between the rolls. Therefore, in order to apply the required pinching pressure, it is preferable to use a rubber having an extremely high hardness, and specifically, the rubber hardness is preferably 80° or more and more preferably 90° or more. However, since the rubber roll and the metal roll lined with rubber have large irregularities on the rubber surface, the smoothness of the film may decrease.

The roll nip length suitable for applying the pinching pressure by the pair of rolls is preferably more than 0 mm and within 5 m, and more preferably more than 0 mm and within 3 mm.

Roll Diameter

As the cast roll, it is preferable to use a roll having a large diameter, and specifically, the diameter is preferably 200 to 1500 mm. It is preferable to use a roll having a large diameter because the deflection of the roll can be reduced and a high pinching pressure can be uniformly applied in a case of pressing. In addition, in the manufacturing method of the present invention, the diameters of the two rolls to be pressed may be the same or different from each other.

Roll Hardness

In order to apply the pressure between rolls in the above-described range, a shore hardness of the roll is preferably 45 HS or more, more preferably 50 HS or more, and particularly preferably 60 to 90 HS. The shore hardness can be obtained from the average value of the values measured at 5 points in the roll width direction and 5 points in the circumferential direction using the method of JIS Z 2246.

Surface Roughness, Cylindricity, Roundness, and Diameter Runout

A surface of the cast roll and/or the touch roll preferably has an arithmetic average surface roughness Ra of 100 nm or less, more preferably 50 nm or less, and particularly preferably 25 nm or less.

The roundness is preferably 5 μm or less, more preferably 3 μm or less, and particularly preferably 2 μm or less. The cylindricity is preferably 5 μm or less, more preferably 3 μm or less, and particularly preferably 2 μm or less. The diameter runout is preferably 7 μm or less, more preferably 4 μm or less, and particularly preferably 3 μm or less. The cylindricity, roundness, and diameter runout can be obtained by the method of JIS B 0621.

Roll Surface Properties

As the cast roll and the touch roll, the surface is preferably a mirror surface, and generally, a roll having a hard chrome-plated surface mirror-finished is used. In addition, it is also preferable to use a roll in which nickel plating is laminated on a hard chrome plating base to prevent corrosion, or to use amorphous chrome plating to reduce the adhesiveness to the roll. Further, in order to improve abrasion resistance and film adhesion to rolls, surface processing such as titanium nitride (TiN), chromium nitride (CrN), or diamond like carbon (DLC) treatment, and Al, Ni, W, Cr, Co, Zr, or Ti-based ceramic spraying can also be performed.

The roll surface is preferably smooth from the viewpoint of film smoothness after film formation, but for surface unevenness formation to impart slipperiness of the film, a mirror pocket surface roll can be used, or a roll which has been blasted or a roll which has been dimpled to form fine irregularities on the film surface can be used. However, from the viewpoint of film smoothness, the unevenness of the roll is preferably Ra=10 μm or less. In addition, it is also possible to use a roll in which 50 to 1000 fine grooves or prism shapes having a depth of 0.1 to 10 μm are engraved on the surface of the roll per 1 mm².

Roll Temperature

It is preferable that the roll can quickly remove the heat supplied from the molten polymer and maintain a constant roll surface temperature. Therefore, it is preferable to pass a medium having a constant temperature inside the roll. As the medium, it is preferable to use water or heat medium oil, and in some cases gas, and select a medium flow rate and medium viscosity capable of sufficient heat exchange. In addition, as a unit for keeping the roll surface temperature constant, a known method can be used, but a roll provided with a spiral flow channel along the circumference of the roll is preferable. A heat pipe can also be used to make the roll temperature uniform.

Molten Polymer Temperature

From the viewpoint of improving the moldability of the liquid crystal polymer component and suppressing deterioration, the discharge temperature (resin temperature at the outlet of the supply unit) is preferably (Tm of liquid crystal polymer component−10°) C. to (Tm of liquid crystal polymer component+40°) C. As a guide for the melt viscosity, 50 to 3500 Pa·s is preferable.

It is preferable that the cooling of the molten polymer between the air gaps is as small as possible, and it is preferable to reduce the temperature drop due to cooling by taking measures such as increasing the film forming speed and shortening the air gap.

Touch Roll Temperature

A temperature of the touch roll is preferably set to Tg or less of the liquid crystal polymer component. In a case where the temperature of the touch roll is Tg or less of the liquid crystal polymer component, the molten polymer can be suppressed from adhering to the roll, so that the film appearance is improved. For the same reason, the chill roll temperature is preferably set to Tg or less of the liquid crystal polymer component.

Film Formation Speed and Circumferential Speed Difference

From the viewpoint of heat retention of the melting in the air gap, a film forming speed is preferably 3 m/min or more, more preferably 5 m/min or more, and particularly preferably 7 m/min or more. In a case where the line speed is increased, cooling of the melt in the air gap can be suppressed, and more uniform pinching pressure and shear deformation can be imparted in a case where the temperature of the melting is high. The film forming speed is defined as the slow second compression surface speed in a case where the molten polymer passes between the two rolls to be pinched.

It is preferable that the moving speed of the first compression surface is faster than the moving speed of the second compression surface. In addition, it is preferable that the film according to the embodiment of the present invention is manufactured by adjusting a moving speed ratio between the first compression surface and the second compression surface of the pinching device to 0.60 to 0.99, and applying shear stress in a case where the molten resin passes through the pinching device. The two compression surfaces may be driven around or independently, but are preferably driven independently from the viewpoint of uniformity of film properties.

(Procedure for Forming Polymer Film)

Film Formation Procedure

In the film forming step, it is preferable to perform the film formation by the following procedure from the viewpoint of film-forming process and the stabilization of quality.

The molten polymer discharged from the die is landed on a cast roll to form a film, which is then cooled and solidified and wound up as a film.

In a case of pressing the molten polymer, the molten polymer is passed between the first compression surface and the second compression surface set at a predetermined temperature, and then is cooled and solidified and wound up as a film.

Transport Tension

A transport tension of the film can be appropriately adjusted depending on the film thickness, and the transport tension per 1 m width of the film is preferably 10 to 500 N/m, more preferably 20 to 300 N/m, and particularly preferably 30 to 200 N/m. Generally, as the film is thicker, it is necessary to increase the transport tension. For example, in the case of a film having a thickness of 100 μm, 30 to 150 N/m is preferable, 40 to 120 N/m is more preferable, and 50 to 100 N/m is particularly preferable. In a case where the transport tension of the film is at least the lower limit value, meandering of the film during film transport can be suppressed, so that slippage between the guide roll and the film can be suppressed and scratches on the film can be suppressed. In a case where the transport tension of the film is the upper limit value or less, it is possible to suppress vertical wrinkles in the film, and it is possible to prevent the film from being forcibly stretched and broken.

For the tension control of the film, any method such as a dancer method, a torque control method using a servo motor, a powder clutch/brake method, and a friction roll control method may be used, but from the viewpoint of control accuracy, a dancer method is preferable. It is not necessary to make all the transport tensions the same value in the film forming step, and it is also useful to adjust the transport tension to an appropriate value for each zone where the tension is cut.

It is preferable that the transport roll has no roll deflection deformation due to transport tension, small mechanical loss, sufficient friction with the film, and a smooth surface so as not to be scratched during film transport. In a case where a transport roll having a small mechanical loss is used, a large tension is not required for transporting the film, and it is possible to suppress scratches on the film. In addition, it is preferable that the transport roll has a large holding angle of the film in order to remove friction with the film. The hugging angle is preferably 90° or more, more preferably 100° or more, and particularly preferably 120° or more. In a case where a sufficient holding angle cannot be obtained, it is preferable to use a rubber roll or a roll having a satin finish, a dimple shape, or a groove on the surface of the roll to secure friction.

Take-Up Tension

It is preferable to appropriately adjust a take-up tension according to the film thickness as well as the film transport tension. The tension per 1 m width of the film is preferably 10 to 500 N/m, more preferably 20 to 300 N/m, and particularly preferably 30 to 200 N/m. Generally, as the film is thicker, it is necessary to increase the tension. For example, in the case of a 100 μm film, the take-up tension is preferably 30 to 150 N/m, more preferably 40 to 120 N/m, and particularly preferably 50 to 100 N/m.

In a case where the take-up tension is the lower limit value or more, meandering of the film during film transport can be suppressed, so that the film can be prevented from slipping and scratching during winding. In a case where the take-up tension is the upper limit value or less, vertical wrinkles can be suppressed in the film, and tight winding of the film can be suppressed to improve the winding appearance. In addition, since the bump portion of the film can be suppressed from extending due to the creep phenomenon, flapping of the film can be suppressed. It is preferable that the take-up tension is detected by the tension control in the middle of the line as in the case of the transport tension, and the take-up tension is controlled so as to be a constant take-up tension. In a case where there is a difference in film temperature depending on the location of the film forming line, the length of the film may differ slightly due to thermal expansion, so that it is preferable to adjust a drawing ratio between the nip rolls so that the film is not tensioned more than specified in the middle of the line. In addition, the take-up tension can be taken up at a constant tension by controlling the tension control, but it is more preferable to taper according to the take-up diameter to obtain an appropriate take-up tension. Generally, the tension is gradually reduced as the winding diameter is increased, but in some cases, it may be preferable to increase the tension as the winding diameter is increased. In addition, there is no problem in the winding direction regardless of which side of the first compression surface or the second compression surface is the winding core side, but in a case where the film is curled, winding it in the direction opposite to the curl has a curl correction effect and may be preferable. It is useful to install edge position control (EPC) to control the meandering of the film during winding, perform oscillation winding to prevent the generation of winding bumps, or to use a roll which eliminates accompanying air during high-speed winding.

Winding Core

The winding core used for winding does not need to be special as long as it has the strength and stiffness required to wind the film, and generally, a paper tube having an inner diameter of 3 to 6 inches or a plastic winding core having an inner diameter of 3 to 14 inches is used. In general, from the viewpoint of low dust generation, a plastic winding core is often used. Although it is cost-effective to use a winding core having a small diameter, a defective winding shape may occur due to bending due to insufficient stiffness, or the film may be curled due to creep deformation at the winding core portion. On the other hand, using a large-diameter winding core is advantageous for maintaining the quality of the film, but may be disadvantageous in terms of handleability and cost. Therefore, it is preferable to appropriately select a winding core of an appropriate size. In addition, it is also possible to provide a cushioning layer on the outer peripheral portion of the winding core to prevent a step corresponding to the film thickness at the winding start portion from being transferred to the film.

Slit

It is preferable that both ends of the formed film are slit in order to obtain a predetermined width. As a slit method, a general method such as a shear cut blade, a Goebel blade, a leather blade, and a rotary blade can be used, but it is preferable to use a cutting method in which dust is not generated during cutting and the burr of the cut portion is small, and cutting with a Goebel blade is preferable. A material of the cutter blade may be either carbon steel or stainless steel, but in general, it is preferable to use a carbide blade or a ceramic blade because the life of the blade is long and the generation of chips is suppressed.

The part cut off by the slit can be crushed and used again as a raw material. After slitting, it may be pulverized and immediately put into an extruder, or it may be pelletized once by an extruder and used. In addition, foreign matter may be removed by filtration in the repelleting step. The blending amount is preferably 0% to 60%, more preferably 5% to 50%, and particularly preferably 10% to 40%. Since recycled raw materials may differ from virgin raw materials in the melt viscosity of the molten polymer or the trace composition produced by thermal degradation, it is necessary to be careful in a case of using the recycled raw materials. It is also useful to control physical properties of the raw material within a certain range by appropriately adjusting the blending amount according to composition of the recycled raw material. In addition, the film in a case of thickness adjustment or switching can be reused in the same manner as the slit selvage.

Knurling Processing

It is also preferable to perform a thickening processing (knurling treatment) on one end or both ends of the film. A height of an unevenness due to the thickening processing is preferably 1 to 50 μm, more preferably 2 to 30 μm, and particularly preferably 3 to 20 μm. In the thickening processing, both sides may be convex or only one side may be convex. A width of the thickening processing is preferably 1 to 50 mm and more preferably 3 to 30 mm. Both cooling and heating can be used for the thickening processing, and in a case where an appropriate method is selected depending on the unevenness formed on the film, the state of dust generation during the thickening processing, and the like. It is also useful to make it possible to identify the film forming direction and the film surface by knurling processing.

Masking Film

It is also preferable to attach a lami-film (masking film) on one side or both sides in order to prevent scratches on the film or improve handleability. A thickness of the lami-film is preferably 5 to 100 μm, more preferably 10 to 70 μm, and particularly preferably 25 to 50 μm.

The masking film is preferably composed of two layers, a base material layer and a pressure-sensitive adhesive layer. As the base material layer, low density polyethylene (LDPE), linear low density polyethylene (LLDPE), high density polyethylene (HDPE), polypropylene (PP), polyester, and the like can be used. As the pressure-sensitive adhesive layer, ethylene vinyl acetate (EVA), acrylic rubber, styrene-based elastomer, natural rubber, and the like can be used. In addition, it is possible to use either the type by a co-extrusion method or the type in which the adhesive material is applied to the film.

An adhesive strength is preferably 0.2 to 2.0 N/25 mm, more preferably 0.3 to 1.5 N/25 mm, and particularly preferably 0.4 to 1.0 N/25 mm. The adhesive strength can be determined by a method according to JIS Z 0237.

Generally, a colorless masking film is often used, but in order to distinguish the front and back of the film, different colors may be used on the front and back. As another method for distinguishing the front and back of the film, it is also effective to attach a masking film having different thickness, adhesive strength, and glossiness of the film surface.

Static Elimination

In a case where the film is charged, dust in the atmosphere is attracted to the film and becomes foreign matter adhering to the film. Therefore, it is preferable that the film being formed, transported, and wound is not charged.

A band voltage is preferably 3 KV or less, more preferably 0.5 KV or less, and particularly preferably 0.05 KV or less.

As a method of preventing the generation of static electricity on the film, various known methods such as a method of preventing the occurrence of static electricity by kneading or applying an antistatic agent to the film, a method of controlling the temperature and humidity of the atmosphere to suppress the generation of static electricity, a method of grounding and releasing static electricity charged on the film, and a method neutralizing with a charge having the opposite sign to the charge using an ionizer, can be used. Among these, a method using an ionizer is common. There are two types of ionizers, a soft X-ray irradiation type and a corona discharge type, and any type can be used. In a case where explosion protection is required, a soft X-ray irradiation type is used, but in general, a corona discharge type is often used. The corona discharge method includes a direct current (DC) type, an alternating current (AC) type, and a pulse AC type, and the pulse AC type is widely used from the viewpoint of performance and cost. The static eliminator may be used alone or in combination of a plurality of types, and the number of static eliminators installed is not particularly limited as long as the film formation is not hindered.

In addition, in order to improve the effect of preventing dust from adhering to the film by static elimination, the environment at the time of film formation is preferably the US federal standard Fed. Std. 209D class 10000 or less, more preferably class 1000 or less, and particularly preferably class 100 or less.

Dust Removal

Foreign matter adhering to the film surface can be removed by a method of pressing a scraper or a brush, a method of ejecting charge-neutralized pressurized air at a pressure of several tens of KPa in order to weaken the attraction effect due to static electricity, a method by suction, or a method in which injection and suction are combined. In addition, known dust removing methods such as a method of pressing a sticky roll against the film and transferring foreign matter to the sticky roll to remove foreign matter and a method of applying ultrasonic waves to the film to suck and remove foreign matter can be used. Further, a method of spraying a liquid on the film and a method of immersing the film in the liquid to wash away foreign matter can also be used. Further, in a case where film powder is generated at the cut part by the cutter or the knurled part, it is also preferable to attach a removing device such as a vacuum nozzle to prevent foreign matter from adhering to the film.

(Stretching and Relaxation Treatment)

Furthermore, after forming the un-stretched film by the above-described method, the un-stretched film may be continuously or discontinuously stretched and/or relaxed. For example, each step can be carried out by the combination of the following (a) to (g). In addition, the order of machine-direction stretching and cross-direction stretching may be reversed, each step of machine-direction stretching and cross-direction stretching may be performed in multiple stages, or diagonal stretching, simultaneous biaxial stretching, or the like may be combined.

(a) Cross-direction stretching

(b) Cross-direction stretching→relaxation treatment

(c) Machine-direction stretching

(d) Machine-direction stretching→relaxation treatment

(e) Machine-direction (cross-direction) stretching→cross-direction (machine-direction) stretching

(f) Machine-direction (cross-direction) stretching→cross-direction (machine-direction) stretching→relaxation treatment

(g) Cross-direction stretching→relaxation treatment→machine-direction stretching→relaxation treatment

Machine-Direction Stretching

The machine-direction stretching can be achieved by making the circumferential speed on the outlet side faster than the circumferential speed on the inlet side while heating between the two pairs of rolls. From the viewpoint of film curl, the film temperature is preferably the same on the front and back surfaces, but in a case where optical characteristics are controlled in the thickness direction, stretching can be performed at different temperatures on the front and back surfaces. The stretching temperature here is defined as the temperature on the lower side of the film surface. The machine-direction stretching step may be carried out in one step or in multiple steps. The film is generally preheated by passing it through a temperature-controlled heating roll, but in some cases, a heater can be used to heat the film. In addition, in order to prevent the film from adhering to the roll, a ceramic roll or the like having improved adhesiveness can also be used.

Cross-Direction Stretching

As the cross-direction stretching step, ordinary cross-direction stretching can be adopted. That is, the normal cross-direction stretching is a cross-direction stretching method in which both ends of the film are gripped by clips and the clips are widened while being heated in an oven using a tenter. For example, methods described in JP1987-035817U (JP-S62-035817U), JP2001-138394A, JP1998-249934A (JP-H10-249934A), JP1994-270246A (JP-H6-270246A), JP1992-030922U (JP-H4-030922U), and JP1987-152721A (JP-S62-152721A) can be used.

A stretching temperature in the cross-direction stretching step can be controlled by blowing air at a desired temperature into the tenter. The film temperature may be the same or different on the front and back surfaces for the same reason as in the machine-direction stretching step. The stretching temperature used here is defined as the temperature on the lower side of the film surface. The cross-direction stretching step may be carried out in one step or in multiple steps. In addition, in a case of performing cross-direction stretching in multiple stages, it may be performed continuously or intermittently by providing a zone in which widening is not performed. For such cross-direction stretching, in addition to the normal cross-direction stretching in which the clip is widened in the width direction in the tenter, the following stretching method for gripping and widening the clip with the clip can also be applied.

Diagonal Stretching

As with normal cross-direction stretching, the clips are widened in the cross direction, but can be stretched diagonally by changing the transportation speed of the left and right clips. For example, methods described in JP2002-022944A, JP2002-086554A, JP2004-325561A, JP2008-23775A, and JP2008-110573A can be used.

Simultaneous Biaxial Stretching

The simultaneous biaxial stretching widens the clip in the cross direction and at the same time stretches or contracts in the machine direction, similar to the normal cross-direction stretching. For example, methods described in JP1980-093520U (JP-555-093520U), JP1988-247021A (JP-563-247021A), JP1994-210726A (JP-H6-210726A), JP1994-278204A (JP-H6-278204A), JP2000-334832A, JP2004-106434A, JP2004-195712A, JP2006-142595A, JP2007-210306A, JP2005-022087A, JP2006-517608B, and JP2007-210306A can be used.

Improvement of Bowing (Axis Misalignment)

In the above-described cross-direction stretching step, since the end part of the film is gripped by the clip, the deformation of the film due to the heat shrinkage stress generated during the heat treatment is large at the center of the film and small at the edges, and as a result, the characteristics in the width direction can be distributed. In a case where a straight line is drawn along the cross direction on the surface of the film before the heat treatment step, the straight line on the surface of the film after the heat treatment step is an arcuate shape in which the center portion is recessed toward the downstream side. This phenomenon is called a bowing phenomenon, and is a cause of disturbing isotropy and widthwise uniformity of the film.

As an improvement method, it is possible to reduce the variation in the orientation angle due to the bowing by performing preheating before such cross-direction stretching and heat fixing after stretching. Either preheating or heat fixing may be performed, but it is more preferable to perform both. It is preferable to perform these preheating and heat fixing by gripping with a clip, that is, it is preferable to perform these preheating and heat fixing continuously with the stretching.

The preheating is preferably performed at a temperature higher than the stretching temperature by approximately 1° C. to 50° C., more preferably higher than 2° C. to 40° C., and particularly preferably higher than 3° C. to 30° C. The preheating time is preferably 1 second to 10 minutes, more preferably 5 seconds to 4 minutes, and particularly preferably 10 seconds to 2 minutes.

During preheating, it is preferable to keep the width of the tenter almost constant. Here, “almost” refers to ±10% of the width of the un-stretched film.

The heat fixing is preferably performed at a temperature 1° C. to 50° C. lower than the stretching temperature, more preferably lower than 2° C. to 40° C., and still more preferably lower than 3° C. to 30° C. Particularly preferably, the temperature is not higher than the stretching temperature and not higher than Tg of the liquid crystal polymer component.

The preheating time is preferably 1 second to 10 minutes, more preferably 5 seconds to 4 minutes, and particularly preferably 10 seconds to 2 minutes. During heat fixing, it is preferable to keep the width of the tenter almost constant. Here, “almost” means 0% (the same width as the tenter width after stretching) to −30% (30% smaller than the tenter width after stretching=reduced width) of the tenter width after the completion of stretching. In a case where the width is expanded more than the stretched width, residual strain is likely to occur in the film. Examples of other known methods include methods described in JP1889-165423A (JP-H1-165423A), JP1992-216326A (JP-H3-216326A), JP2002-018948A, and JP2002-137286A.

Relaxation Treatment

The heat shrinkage rate can be reduced by performing a heat relaxation treatment under the following conditions after the above-described stretching. It is preferable that the heat relaxation treatment is carried out at at least one timing after film formation, machine-direction stretching, or cross-direction stretching. The relaxation treatment may be continuously performed online after the stretching, or may be performed offline after winding after the stretching. The treatment temperature may be Tg or higher and the melting point or lower, and in a case where there is concern about oxidative deterioration of the film, the heat relaxation treatment may be performed in an inert gas such as nitrogen gas, argon gas, and helium gas.

(Surface Treatment)

By surface-treating the film, it is possible to improve the adhesion with the copper foil or the copper plating layer used for the copper-clad laminate. For example, glow discharge treatment, ultraviolet irradiation treatment, corona treatment, flame treatment, or acid or alkali treatment can be used. The aforementioned glow discharge treatment may be a treatment with a low-temperature plasma generated in a gas at a low pressure ranging from 10⁻³ to 20 Torr, and is preferably a plasma treatment under atmospheric pressure.

A plasma-excited gas refers to a gas that is plasma-excited under the above-described conditions. Examples thereof include fluorocarbons such as argon, helium, neon, krypton, xenon, nitrogen, carbon dioxide, and tetrafluoromethane, mixtures of these, and the like. It is also preferable to provide an undercoat layer for adhesion to the copper foil or the copper plating layer. This layer may be applied after the above-described surface treatment, or may be applied without the surface treatment. These surface treatment and undercoating steps can be incorporated at the end of the film forming step, can be carried out independently, or can be carried out in the copper foil or copper plating layer applying step.

(Aging)

It is also useful to age the film at a temperature of Tg or lower of the liquid crystal polymer component in order to improve the mechanical properties, thermal dimensional stability, or winding shape of the wound film.

(Storage Conditions)

In order to prevent wrinkles and bumps from being generated due to the relaxation of residual strain of the wound film, it is preferable to store the film in a temperature environment of Tg or lower of the liquid crystal polymer component. In addition, the temperature is preferably less variable, and the temperature fluctuation per hour is preferably 30° C. or lower, more preferably 20° C. or lower, and particularly preferably 10° C. or lower. Similarly, in order to prevent changes in the hygroscopicity of the film and prevent condensation, the humidity is preferably 10% to 90%, more preferably 20% to 80%, and particularly preferably 30% to 70%, and the temperature fluctuation per hour is preferably 30% or less, more preferably 20% or less, and particularly preferably 10% or less. In a case where the storage is required in a place where the temperature and humidity fluctuate, it is also effective to use a packaging material having moisture-proof or heat-insulating properties.

In the above, the film has a single layer, but may have a laminated structure in which a plurality of layers are laminated.

After the film forming step, the smoothness of the film may be further improved through a step of pressing the film with a heating roll and/or a step of stretching the film.

[Use of Polymer Film]

The liquid crystal polymer film according to the embodiment of the present invention can be used in a form of a film substrate, a flexible copper-clad laminate laminated with a copper foil, a flexible printed wiring board (FPC), a laminated circuit board, and the like.

Among these, the liquid crystal polymer film according to the embodiment of the present invention is preferably used for a substrate for high-speed communication having the liquid crystal polymer film according to the embodiment of the present invention.

### EXAMPLES

Examples and Comparative Examples of the present invention will be described.

Liquid crystal polymer films of Examples 1 to 34 and Comparative Example 1 were manufactured by a manufacturing method shown below, and evaluated as follows. First, the manufacturing method of each of Examples and Comparative Example will be described.

[Material]

Materials used to manufacture the liquid crystal polymer film are shown below.

[Liquid Crystal Polymer Component]
LCP1: LAPEROS C-950 manufactured by Polyplastics Co., Ltd., melting point: approximately 320° C.; corresponding to a thermotropic liquid crystal polymer
LCP2: LAPEROS A-950 manufactured by Polyplastics Co., Ltd., melting point: approximately 280° C.; corresponding to a thermotropic liquid crystal polymer

Both LCP1 and LCP2 are polymers represented by the following chemical formulae. However, the content ratio of each repeating unit constituting both polymers is different.

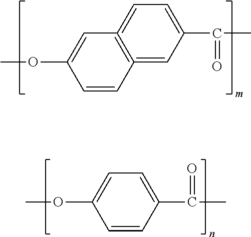

[Polyolefin Component]

The following PE1 to PE6 are products with different product numbers in the same series, and each has a different MFR.
PE1: Novatec LD (low density polyethylene) manufactured by Japan Polyethylene Corporation
PE2: Novatec LD (low density polyethylene) manufactured by Japan Polyethylene Corporation
PE3: Novatec LD (low density polyethylene) manufactured by Japan Polyethylene Corporation
PE4: Novatec LD (low density polyethylene) manufactured by Japan Polyethylene Corporation
PE5: Novatec LD (low density polyethylene) manufactured by Japan Polyethylene Corporation
PE6: Novatec LD (low density polyethylene) manufactured by Japan Polyethylene Corporation
PP1: Novatec PP (polypropylene) manufactured by Japan Polypropylene Corporation
SEBS1: TUFTEC (SEBS copolymer) manufactured by Asahi Kasei Corporation

[Compatible Component]
E-GMA: Bondfast E (E-GMA copolymerization) manufactured by Sumitomo Chemical Company
E-MAH: ADMER (E-MAH copolymerization) manufactured by Mitsui Chemicals,

Inc.
SEBS-NH2: TUFTEC (SEBS-NH2 copolymerization (amine-modified SEBS)) manufactured by Asahi Kasei Corporation

[Heat Stabilizer]
Heat stabilizer 1: Irganox 1010 (hindered phenol-based stabilizer) manufactured by BASF
Heat stabilizer 2: ADK STAB PEP-36 (phosphite-based stabilizer) manufactured by ADEKA Corporation

[Manufacturing]

A liquid crystal polymer film was manufactured by a method shown below.

[Supplying Step]

Components (liquid crystal polymer component, olefin component, compatible component, and/or heat stabilizer) shown in the tables shown in the latter part were mixed in the same composition as shown in the tables, and kneaded and pelletized using an extruder. The pellets obtained by kneading and pelletizing were dried at 80° C. using a dehumidifying hot air dryer having a dew point temperature of −45° C. for 12 hours to reduce the moisture content to 50 ppm or less.

The pellets dried in this way are also referred to as a raw material A.

[Film Forming Step]

The raw material A was supplied into a cylinder from the same supply port of a biaxial extruder having a screw diameter of 50 mm, heat-kneaded, discharged from a die having a die width of 750 mm onto a rotating cast roll in a form of a film, cooled and solidified, and appropriately stretched as desired to obtain a liquid crystal polymer film having a thickness of 100 μm.

The temperature of heat kneading, the discharge rate in a case of discharging the raw material A, the clearance of the die lip, and the circumferential speed of the cast roll were adjusted in the following ranges so as to obtain the dispersed phase as shown in the tables below.
Temperature of heat kneading: 270° C. to 350° C.
Clearance: 0.01 to 5 mm
Discharge rate: 0.1 to 1000 mm/sec
Circumferential speed of cast roll: 0.1 to 100 m/min

[Measurement]

The following measurements were performed for each liquid crystal polymer film obtained by the above-described method.

[Average Dispersion Diameter]

A scanning electron microscope was used to observe the dispersed phase of the olefin component in the liquid crystal polymer film.

At 10 different sites on a sample, a fractured surface parallel to a width direction of the liquid crystal polymer film and perpendicular to a film surface and a fractured surface perpendicular to the width direction of the liquid crystal polymer film and perpendicular to the film surface were observed to obtain a total of 20 observation images. The observation was carried out at an appropriate magnification of 100 to 100000 times, and images were taken so that the dispersed state of the particles (dispersed phase formed by the olefin component) in the width of the entire thickness of the liquid crystal polymer film could be confirmed.

For 200 particles randomly selected from each of the 20 images, the outer circumference of each particle was traced, and the equivalent circle diameter of the particles was measured from these trace images with an image analyzer to determine the particle size. The average value of the particle size measured from each image taken was defined as the average dispersion diameter.

[Lx, Ly, and Lz]

For 200 particles randomly selected from each of the 10 observation images having a fractured surface parallel to the width direction of the liquid crystal polymer film obtained above and perpendicular to the film surface, the outer circumference of each particle (dispersed phase formed by the olefin component) was traced, the diameter in the film width direction of the particles was measured from these trace images with an image analyzer, and the average value was obtained and defined as Lx (μm). In addition, the diameter in the film thickness direction of the particles was measured, and the average value was obtained and defined as Lz1 (μm).

For 200 particles randomly selected from each of the 10 observation images having a fractured surface perpendicular to the width direction of the liquid crystal polymer film obtained above and perpendicular to the film surface, the outer circumference of each particle (dispersed phase formed by the olefin component) was traced, the diameter in the film longitudinal direction of the particles was measured from these trace images with an image analyzer, and the average value was obtained and defined as Ly (μm). In addition, the diameter in the film thickness direction of the particles was measured, and the average value was obtained and defined as Lz2 (μm).

The average value of Lz1 and Lz2 was obtained and defined as Lz (μm).

Values of Ly/Lx, Lz/Lx, and Lz/Ly were calculated using the values of Lx, Ly, and Lz obtained for each liquid crystal polymer film.

[Melting Point (Tm)]

A center portion of the obtained liquid crystal polymer film was sampled, and a melting point Tm of the liquid crystal polymer film was measured by DSC (DSC-60A manufactured by Shimadzu Corporation).

The heating rate was 10° C./min.

The temperature at the top of the endothermic peak during melting was taken as the melting point.

[MFR]

Melt flow rate (MFR) was measured for the liquid crystal polymer film and the components A and B obtained by treating the liquid crystal polymer film by the method shown below. The MFR value was in accordance with JIS K 7210, the temperature was the melting point (Tm) of the liquid crystal polymer film measured by the above-described method, and the load was 5 kgf.

A plurality of test pieces obtained by cutting out the center portion of the obtained liquid crystal polymer film in a size of 10 cm×10 cm were obtained and pulverized. The obtained pulverized product was immersed in dichloromethane. In this case, the amount of the solvent was 1000 times (based on mass) of the amount of the pulverized material to be immersed. After sufficiently eluting the soluble component soluble in dichloromethane from the pulverized product, the above-described dichloromethane (eluate) was filtered and separated into a residue and a filtrate. The obtained residue was dried at normal temperature (25° C.) to obtain the component A.

Next, the above-described filtrate was added dropwise to ethanol 1000 times the mass of the above-described filtrate to precipitate a precipitate in ethanol. The ethanol was filtered and separated into a residue and a filtrate, and the obtained residue was dried at normal temperature (25° C.) to obtain the component B.

In the series of steps, the temperature of the liquid crystal polymer film, the temperature of dichloromethane and ethanol, and the working temperature were all set to 25° C.

[η(Tm−30° C.) and η(Tm+30° C.)]

A viscosity of the obtained liquid crystal polymer film was measured.

A melt viscosity at Tm−30° C. and shear rate of 1000 sec⁻¹ was determined by a measurement in accordance with JIS K 7199 using a capillary rheometer TOYO SEIKI KOGYO CO., LTD., and was defined as η(Tm−30° C.). Similarly, a melt viscosity at Tm+30° C. and shear rate of 1000 sec⁻¹ was determined, and was defined as η(Tm+30° C.).

The values of η(Tm−30° C.) and η(Tm+30° C.) obtained for each liquid crystal polymer film were used to calculate a value of η(Tm+30° C.)/η(Tm−30° C.).

[Surface Roughness Ra]

A surface roughness (maximum height) Ra of the liquid crystal polymer film was measured using a stylus type roughness meter according to JIS B 0601. For the measurement of Ra, 5 randomly selected points within the center of 10 cm×10 cm of the film were measured, and the average value was obtained.

[Evaluation]

Each liquid crystal polymer film was evaluated by the method shown below.

[Surface Properties (Plane)]

Surface properties of the liquid crystal polymer film were visually evaluated according to the following standard.

A: There was no mesh-like unevenness.

B: There was slight mesh-like unevenness.

C: There was uneven mesh-like unevenness.

D: There was remarkable mesh-like unevenness.

[Smoothness (Surface Roughness Ra)]

Smoothness of the liquid crystal polymer film was evaluated by the following standard using the surface roughness Ra value.

A: less than 300 nm

B: 300 nm or more and less than 400 nm

C: 400 nm or more and less than 430 nm

D: 430 nm or more

[Anisotropy]

In order to evaluate anisotropy of the liquid crystal polymer film, a test piece obtained by cutting out the center portion of the liquid crystal polymer film into a size of 10 cm×10 cm was placed on a flat surface and heated at 300° C. for 10 seconds in the air. The state of wrinkles caused by the anisotropy of dimensional deformation in the width direction or the longitudinal direction of the liquid crystal polymer film was investigated and visually evaluated according to the following standard.

A: There were no wrinkles

B: Wrinkles occurred slightly

C: Wrinkles occurred

D: Wrinkles were noticeable

[Result]

Features and evaluation results of each liquid crystal polymer film are shown in the following tables (Tables 1 and 2).

In the tables, in the columns of “Olefin component” and “Compatible component”, the column of “Concentration” indicates the content (wt %) of each component with respect to the total mass of the liquid crystal polymer film.

The column of “MFR” in the columns of “Liquid crystal polymer component” and “Olefin component” indicates MFR of the liquid crystal polymer component or the olefin component measured with a load of 5 kgf in accordance with JIS K7210 at the melting point of the produced liquid crystal polymer film.

The column of “Concentration” in the column of “Heat stabilizer” indicates the content of the heat stabilizer in the liquid crystal polymer film. More specifically, the content (part by mass) of the heat stabilizer with respect to 100 parts by mass of the olefin component in the liquid crystal polymer film is shown.

The components (residue) other than the olefin component, the compatible component, and the heat stabilizer in the liquid crystal polymer film are the liquid crystal polymer components.

The column of “Compatible component/olefin” indicates the content (% by mass) of the compatible component with respect to 100% by mass of the content of the olefin component.

The column of “Functional group” indicates the type of characteristic functional group included in the compatible component. “Epoxy” means that the compatible component has an epoxy group, “Maleic acid anhydride” means that the compatible component has a maleic acid anhydride group, and “Amine” means that the compatible component has an amino group.

The column of “MFR ratio” indicates the ratio (MFR of component B/MFR of component A) of MFR of the component B to MFR of the component A measured by the above-described method.

The column of “Film MFR” indicates the MFR at the melting point of the produced liquid crystal polymer film.

TABLE 1

| | Formulation | | | | | | | | | | |
|---|---|---|---|---|---|---|---|---|---|---|---|
| | Liquid crystal polymer | | Olefin component | | | Compatible component | | | Heat stabillizer | | Compatible |
| | component | | | Concen- | | | | Concen- | | Concen- | component/ |
| | | MFR | Type | tration | MFR | | Functional | tration | | tration | olefin |
| | Type | g/min | — | wt % | g/min | Type | group | wt % | Type | phr | % |
| Example 1 | LCP1 | 8 | PE1 | 12 | 2.7 | E-GMA | Epoxy | 2.4 | Heat stabilizer | 0.1 | 20.0 |
| | | | | | | | | | 1 | | |
| Example 2 | LCP1 | 8 | PE1 | 12 | 2.7 | E-GMA | Epoxy | 7.5 | Heat stabilizer | 0.1 | 62.5 |
| | | | | | | | | | 1 | | |
| Example 3 | LCP1 | 8 | PE1 | 12 | 2.7 | E-GMA | Epoxy | 0.6 | Heat stabilizer | 0.1 | 5.0 |
| | | | | | | | | | 1 | | |
| Example 4 | LCP1 | 8 | PE1 | 12 | 2.7 | E-GMA | Epoxy | 0.5 | Heat stabilizer | 0.1 | 4.2 |
| | | | | | | | | | 1 | | |
| Example 5 | LCP1 | 8 | PE1 | 12 | 2.7 | E-GMA | Epoxy | 0.1 | Heat stabilizer | 0.1 | 0.8 |
| | | | | | | | | | 1 | | |
| Example 6 | LCP1 | 8 | PE1 | 12 | 2.7 | — | — | 0 | Heat stabilizer | 0.1 | 0.0 |
| | | | | | | | | | 1 | | |
| Example 7 | LCP1 | 8 | PE1 | 12 | 2.7 | E-MAH | Maleic acid | 2.4 | Heat stabilizer | 0.1 | 20.0 |
| | | | | | | | anhydride | | 1 | | |
| Example 8 | LCP1 | 8 | PE1 | 12 | 2.7 | SEBS-NH2 | Amino | 2.4 | Heat stabilizer | 0.1 | 20.0 |
| | | | | | | | | | 1 | | |
| Example 9 | LCP1 | 8 | PE1 | 12 | 2.7 | E-GMA | Epoxy | 2.4 | Heat stabilizer | 0.1 | 20.0 |
| | | | | | | | | | 2 | | |
| Example 10 | LCP1 | 8 | PE1 | 12 | 2.7 | E-GMA | Epoxy | 2.4 | — | 0 | 20.0 |
| Example 11 | LCP1 | 8 | PE1 | 0.2 | 2.7 | E-GMA | Epoxy | 0.04 | Heat stabilizer | 0.1 | 20.0 |
| | | | | | | | | | 1 | | |
| Example 12 | LCP1 | 8 | PE1 | 5 | 2.7 | E-GMA | Epoxy | 1.0 | Heat stabilizer | 0.1 | 20.0 |
| | | | | | | | | | 1 | | |
| Example 13 | LCP1 | 8 | PE1 | 25 | 2.7 | E-GMA | Epoxy | 5.0 | Heat stabilizer | 0.1 | 20.0 |
| | | | | | | | | | 1 | | |
| Example 14 | LCP1 | 8 | PE1 | 40 | 2.7 | E-GMA | Epoxy | 8.0 | Heat stabilizer | 0.1 | 20.0 |
| | | | | | | | | | 1 | | |
| Example 15 | LCP1 | 8 | PE1 | 42 | 2.7 | E-GMA | Epoxy | 8.4 | Heat stabilizer | 0.1 | 20.0 |
| | | | | | | | | | 1 | | |
| Example 16 | LCP1 | 8 | PE2 | 12 | 0.8 | E-GMA | Epoxy | 2.4 | Heat stabilizer | 0.1 | 20.0 |
| | | | | | | | | | 1 | | |
| Example 17 | LCP1 | 8 | PE3 | 12 | 8.2 | E-GMA | Epoxy | 2.4 | Heat stabilizer | 0.1 | 20.0 |
| | | | | | | | | | 1 | | |
| Example 18 | LCP1 | 8 | PE4 | 12 | 80 | E-GMA | Epoxy | 2.4 | Heat stabilizer | 0.1 | 20.0 |
| | | | | | | | | | 1 | | |
| Example 19 | LCP1 | 8 | PE5 | 12 | 0.6 | E-GMA | Epoxy | 2.4 | Heat stabilizer | 0.1 | 20.0 |
| | | | | | | | | | 1 | | |
| Example 20 | LCP1 | 8 | PE6 | 12 | 90 | E-GMA | Epoxy | 2.4 | Heat stabilizer | 0.1 | 20.0 |
| | | | | | | | | | 1 | | |
| Example 21 | LCP1 | 8 | PE1 | 12 | 2.7 | E-GMA | Epoxy | 2.4 | Heat stabilizer | 0.1 | 20.0 |
| | | | | | | | | | 1 | | |
| Example 22 | LCP1 | 8 | PE1 | 12 | 2.7 | E-GMA | Epoxy | 2.4 | Heat stabilizer | 0.1 | 20.0 |
| | | | | | | | | | 1 | | |
| Example 23 | LCP1 | 8 | PE1 | 12 | 2.7 | E-GMA | Epoxy | 2.4 | Heat stabilizer | 0.1 | 20.0 |
| | | | | | | | | | 1 | | |
| Example 24 | LCP1 | 8 | PE1 | 12 | 2.7 | E-GMA | Epoxy | 2.4 | Heat stabilizer | 0.1 | 20.0 |
| | | | | | | | | | 1 | | |
| Example 25 | LCP1 | 8 | PE1 | 12 | 2.7 | E-GMA | Epoxy | 2.4 | Heat stabilizer | 0.1 | 20.0 |
| | | | | | | | | | 1 | | |
| Example 26 | LCP1 | 8 | PE1 | 12 | 2.7 | E-GMA | Epoxy | 2.4 | Heat stabilizer | 0.1 | 20.0 |
| | | | | | | | | | 1 | | |
| Example 27 | LCP1 | 8 | PE1 | 12 | 2.7 | E-GMA | Epoxy | 2.4 | Heat stabilizer | 0.1 | 20.0 |
| | | | | | | | | | 1 | | |
| Example 28 | LCP1 | 8 | PE1 | 12 | 2.7 | E-GMA | Epoxy | 2.4 | Heat stabilizer | 0.1 | 20.0 |
| | | | | | | | | | 1 | | |
| Example 29 | LCP1 | 8 | PE1 | 12 | 2.7 | E-GMA | Epoxy | 2.4 | Heat stabilizer | 0.1 | 20.0 |
| | | | | | | | | | 1 | | |
| Example 30 | LCP1 | 8 | PP1 | 12 | 4.0 | E-GMA | Epoxy | 2.4 | Heat stabilizer | 0.1 | 20.0 |
| | | | | | | | | | 1 | | |
| Example 31 | LCP1 | 8 | SEBS1 | 12 | 1.0 | E-GMA | Epoxy | 2.4 | Heat stabilizer | 0.1 | 20.0 |
| | | | | | | | | | 1 | | |
| Example 32 | LCP2 | 4 | PE1 | 12 | 2.3 | E-GMA | Epoxy | 2.4 | Heat stabilizer | 0.1 | 20.0 |
| | | | | | | | | | 1 | | |
| Comparative | LCP1 | 8 | None | 0 | — | — | — | 0.0 | Heat stabilizer | 0.1 | — |
| example 1 | | | | | | | | | 1 | | |

TABLE 2

| | | Dispersed phase | | | | | | | | | | | | |
|---|---|---|---|---|---|---|---|---|---|---|---|---|---|---|
| | | Average | | | | | | | Pysical propeties | | | | | |
| | | dispersion | | | | | | | Film | | | Evaluation | | |
| | MFR | diameter | Lx | Ly | Lz | Ly/Lx | Lz/Lx | Lz/Ly | MFR | η(Tm + 30)/ | Ra | | Surface | |
| | ratio | μm | μm | μm | μm | — | — | — | g/min | η(Tm − 30) | nm | Plane | roughness | Anisotropy |
| Example 1 | 0.34 | 2.1 | 2.9 | 2.4 | 0.9 | 0.83 | 0.31 | 0.38 | 7.4 | 0.064 | 193 | A | A | A |
| Example 2 | 0.34 | 2.0 | 2.7 | 2.4 | 0.8 | 0.89 | 0.30 | 0.33 | 7.4 | 0.064 | 188 | A | A | A |
| Example 3 | 0.34 | 2.6 | 3.5 | 3.3 | 1.1 | 0.94 | 0.31 | 0.33 | 7.4 | 0.063 | 199 | A | A | A |
| Example 4 | 0.34 | 5.1 | 7.1 | 5.9 | 2.2 | 0.83 | 0.31 | 0.37 | 7.4 | 0.062 | 250 | A | A | A |
| Example 5 | 0.34 | 8.7 | 12.2 | 10.2 | 3.6 | 0.84 | 0.30 | 0.35 | 7.4 | 0.061 | 366 | B | B | B |
| Example 6 | 0.34 | 10.8 | 15.8 | 12.2 | 4.5 | 0.77 | 0.28 | 0.37 | 7.4 | 0.058 | 406 | B | C | B |
| Example 7 | 0.34 | 2.6 | 3.8 | 2.9 | 1.1 | 0.76 | 0.29 | 0.38 | 7.4 | 0.063 | 243 | A | A | A |
| Example 8 | 0.34 | 2.9 | 4.3 | 3.1 | 1.2 | 0.72 | 0.28 | 0.39 | 7.4 | 0.062 | 221 | A | A | B |
| Example 9 | 0.34 | 2.1 | 2.8 | 2.5 | 0.9 | 0.89 | 0.32 | 0.36 | 7.4 | 0.064 | 198 | A | A | A |
| Example 10 | 0.34 | 2.1 | 3.0 | 2.4 | 0.9 | 0.80 | 0.30 | 0.38 | 7.4 | 0.064 | 404 | A | C | A |
| Example 11 | 0.34 | 1.8 | 2.6 | 2.1 | 0.8 | 0.81 | 0.31 | 0.38 | 8.0 | 0.030 | 196 | C | A | B |
| Example 12 | 0.34 | 1.9 | 2.6 | 2.2 | 0.8 | 0.85 | 0.31 | 0.36 | 7.7 | 0.040 | 199 | B | A | B |
| Example 13 | 0.34 | 2.3 | 3.1 | 2.8 | 1.1 | 0.90 | 0.35 | 0.39 | 6.7 | 0.150 | 302 | A | B | A |
| Example 14 | 0.34 | 3.9 | 5.1 | 4.8 | 1.7 | 0.94 | 0.33 | 0.35 | 5.9 | 0.210 | 385 | A | B | A |
| Example 15 | 0.34 | 4.5 | 6.1 | 5.5 | 1.8 | 0.90 | 0.30 | 0.33 | 5.8 | 0.220 | 401 | A | C | A |
| Example 16 | 0.10 | 3.1 | 4.3 | 3.7 | 1.4 | 0.86 | 0.33 | 0.38 | 7.1 | 0.050 | 302 | B | B | A |
| Example 17 | 1.0 | 1.4 | 1.8 | 1.7 | 0.6 | 0.94 | 0.33 | 0.35 | 8.0 | 0.063 | 188 | A | A | A |
| Example 18 | 10.0 | 3.7 | 5.1 | 4.4 | 1.6 | 0.86 | 0.31 | 0.36 | 16.6 | 0.050 | 309 | B | B | A |
| Example 19 | 0.08 | 5.5 | 7.1 | 6.9 | 2.4 | 0.97 | 0.34 | 0.35 | 7.1 | 0.045 | 405 | B | C | B |
| Example 20 | 11.3 | 6.1 | 8 | 7.5 | 2.7 | 0.94 | 0.34 | 0.36 | 17.8 | 0.047 | 420 | B | C | B |
| Example 21 | 0.34 | 0.05 | 0.07 | 0.06 | 0.02 | 0.86 | 0.29 | 0.33 | 7.4 | 0.064 | 176 | A | A | A |
| Example 22 | 0.34 | 3.5 | 8.2 | 1.2 | 1.0 | 0.1 | 0.12 | 0.83 | 7.4 | 0.064 | 206 | B | A | C |
| Example 23 | 0.34 | 3.6 | 1.1 | 8.6 | 1.0 | 7.8 | 0.91 | 0.12 | 7.4 | 0.064 | 214 | B | A | C |
| Example 24 | 0.34 | 4.8 | 12.5 | 1.1 | 0.8 | 0.09 | 0.064 | 0.73 | 7.4 | 0.064 | 225 | C | A | C |
| Example 25 | 0.34 | 5.2 | 1.2 | 13.1 | 1.2 | 10.9 | 1.0 | 0.09 | 7.4 | 0.064 | 209 | C | A | C |
| Example 26 | 0.34 | 10.4 | 16.5 | 14.4 | 0.3 | 0.87 | 0.018 | 0.021 | 7.4 | 0.064 | 371 | B | B | A |
| Example 27 | 0.34 | 2.1 | 2.2 | 2.1 | 1.9 | 1.0 | 0.86 | 0.90 | 7.4 | 0.064 | 211 | B | A | B |
| Example 28 | 0.34 | 14.3 | 21.5 | 21.3 | 0.2 | 1.0 | 0.009 | 0.009 | 7.4 | 0.064 | 385 | C | B | A |
| Example 29 | 0.34 | 2.3 | 2.3 | 2.2 | 2.4 | 1.0 | 1.0 | 1.1 | 7.4 | 0.064 | 243 | C | A | B |
| Example 30 | 0.50 | 3.3 | 4.6 | 3.8 | 1.4 | 0.83 | 0.30 | 0.37 | 7.5 | 0.054 | 314 | C | B | B |
| Example 31 | 0.13 | 3.8 | 5.1 | 4.6 | 1.8 | 0.90 | 0.35 | 0.39 | 7.2 | 0.052 | 348 | C | B | A |
| Example 32 | 0.58 | 1.7 | 2.3 | 2.1 | 0.8 | 0.91 | 0.35 | 0.38 | 3.8 | 0.066 | 186 | A | A | A |
| Comparative | — | — | — | — | — | — | — | — | 8.0 | 0.028 | 442 | D | D | D |
| example 1 | | | | | | | | | | | | | | |

From the results shown in the above tables, it was confirmed that the liquid crystal polymer film according to the embodiment of the present invention can solve the problems of the present invention.

In addition, from the viewpoint that the effects of the present invention were more excellent, it was confirmed that the liquid crystal polymer film preferably included the compatible component, and it was more preferable that the compatible component had an epoxy group or a maleic acid anhydride group (comparison of Examples 1, and 6 to 8, and the like).

From the viewpoint that the effects of the present invention were more excellent, it was confirmed that the content of the compatible component was preferably 1% by mass or more with respect to 100% by mass of the content of the olefin component (comparison of Examples 1 to 5, and the like).

From the viewpoint that the effects of the present invention were more excellent, it was confirmed that the content of the compatible component was preferably 0.5% by mass or more with respect to total mass of the liquid crystal polymer film (comparison of Examples 1 to 5, and the like).

From the viewpoint that the effects of the present invention were more excellent, it was confirmed that the olefin component was preferably polyethylene or SEBS and more preferably polyethylene (comparison of Examples 1, 30 and 31, and the like).

From the viewpoint that the effects of the present invention were more excellent, it was confirmed that the content of the olefin component was preferably 5% by mass or more and more preferably 10% by mass or more with respect to total mass of the liquid crystal polymer film. In addition, it was confirmed that the above-described content was preferably 40% by mass or less and more preferably 15% by mass or less (comparison of Examples 1, 11 to 15, and the like).

From the viewpoint that the effects of the present invention were more excellent, the ratio (MFR^{B}/MFR^{A}) of MFR (MFR^{B}) of the component B to MFR (MFR^{A}) of the component A was preferably in a range of 0.10 to 10.0 and more preferably in a range of more than 0.10 and 2.0 or less (comparison of Examples 1, 16 to 20, and the like).

The above-described MFR is MFR measured under the above-described conditions.

From the viewpoint that the surface properties and smoothness of the liquid crystal polymer film were more excellent, it was confirmed that the average dispersion diameter of the dispersed phase was preferably 10.0 μm or less (comparison of Examples 1, 21 to 29, and the like).

From the viewpoint that the effects of the present invention were more excellent, it was confirmed that it was preferable that Ly/Lx was 0.10 to 10.0 (more preferably 0.20 to 5.0), Lz/Lx was 0.010 to 1.0 (more preferably 0.15 to 0.50), and/or Lz/Ly was 0.010 to 1.0 (more preferably 0.15 to 0.50) (comparison of Examples 1, 21 to 29, and the like).

What is claimed is:

1. A liquid crystal polymer film comprising:
a liquid crystal polymer component; and
at least one component selected from the group consisting of an olefin component, a cross-linking component, and a compatible component.

2. The liquid crystal polymer film according to claim 1,
wherein the liquid crystal polymer film includes the liquid crystal polymer component, the olefin component, and the compatible component.

3. The liquid crystal polymer film according to claim 1,
wherein the liquid crystal polymer film includes the liquid crystal polymer component, the olefin component, the compatible component, and a heat stabilizer.

4. The liquid crystal polymer film according to claim 1,
wherein the liquid crystal polymer component is a thermotropic liquid crystal polymer.

5. The liquid crystal polymer film according to claim 1,
wherein the liquid crystal polymer film includes the olefin component, and
a content of the olefin component in the liquid crystal polymer film is 0.1% to 40% by mass with respect to a total mass of the liquid crystal polymer film.

6. The liquid crystal polymer film according to claim 1,
wherein the liquid crystal polymer film includes the olefin component,
the olefin component forms a dispersed phase in the liquid crystal polymer film, and
an average dispersion diameter of the dispersed phase is 0.01 to 10 μm.

7. The liquid crystal polymer film according to claim 6,
wherein, in the liquid crystal polymer film, in a case where a length of the dispersed phase in a width direction is defined as Lx and a length of the dispersed phase in a longitudinal direction is defined as Ly, Expression (1A) is satisfied,
$$0.10 \leq Ly / Lx \leq 10.0 . \qquad ( 1 A )$$

8. The liquid crystal polymer film according to claim 6,
wherein, in the liquid crystal polymer film, in a case where a length of the dispersed phase in a width direction is defined as Lx, a length of the dispersed phase in a longitudinal direction is defined as Ly, and a length of the dispersed phase in a thickness direction is defined as Lz, Expression (2A) and Expression (3A) are satisfied,
$$0.010 \leq Lz / Lx \leq 1. \qquad ( 2 A )$$
$$0.01 0 \leq Lz / Ly \leq 1.0 . \qquad ( 3 A )$$

9. The liquid crystal polymer film according to claim 1,
wherein, in a case where a viscosity of the liquid crystal polymer film at a temperature lower than a melting point of the liquid crystal polymer film by 30° C. is defined as η(Tm−30° C.) and a viscosity of the liquid crystal polymer film at a temperature higher than the melting point of the liquid crystal polymer film by 30° C. is defined as η(Tm+30° C.), Expression (4A) is satisfied,
$$η ( T m + 30 ° C . ) / η ( Tm - 30 ° C . ) \geq 0.02 . \qquad ( 4 A )$$

10. The liquid crystal polymer film according to claim 1,
wherein MFRs of a component A and a component B satisfy a relationship represented by Expression (5A), the MFRs of the component A and the component B being obtained by performing, in the following order,
a step of immersing the liquid crystal polymer film in dichloromethane in an amount of 1000 times a mass of the liquid crystal polymer film to produce an eluate in which a soluble component of the liquid crystal polymer film to the dichloromethane is eluted in the dichloromethane,
a step of filtrating the eluate to be separated into the component A, which is a residue, and a filtrate,
a step of dropwise adding the filtrate to ethanol to precipitate a precipitate in the ethanol, and
a step of filtrating the ethanol to be separated into the component B, which is a residue, and a filtrate,
$$0.10 \leq M F {R}^{B} / MF {R}^{A} \leq 10.0 \qquad ( 5 A )$$
MFR^{A}: MFR of the component A at a load of 5 kgf at the melting point of the liquid crystal polymer film
MFR^{B}: MFR of the component B at a load of 5 kgf at the melting point of the liquid crystal polymer film.

11. The liquid crystal polymer film according to claim 1,
wherein the olefin component is polyethylene.

12. The liquid crystal polymer film according to claim 1,
wherein a surface roughness Ra is less than 430 nm.

13. A substrate for high-speed communication comprising:
the liquid crystal polymer film according to claim 1.

14. The liquid crystal polymer film according to claim 2,
wherein the liquid crystal polymer film includes the liquid crystal polymer component, the olefin component, the compatible component, and a heat stabilizer.

15. The liquid crystal polymer film according to claim 2,
wherein the liquid crystal polymer component is a thermotropic liquid crystal polymer.

16. The liquid crystal polymer film according to claim 2,
wherein the liquid crystal polymer film includes the olefin component, and
a content of the olefin component in the liquid crystal polymer film is 0.1% to 40% by mass with respect to a total mass of the liquid crystal polymer film.

17. The liquid crystal polymer film according to claim 2,
wherein the liquid crystal polymer film includes the olefin component,
the olefin component forms a dispersed phase in the liquid crystal polymer film, and
an average dispersion diameter of the dispersed phase is 0.01 to 10 μm.

18. The liquid crystal polymer film according to claim 17,
wherein, in the liquid crystal polymer film, in a case where a length of the dispersed phase in a width direction is defined as Lx and a length of the dispersed phase in a longitudinal direction is defined as Ly, Expression (1A) is satisfied,
$$0.10 \leq Ly / Lx \leq 10.0 . \qquad ( 1 A )$$

19. The liquid crystal polymer film according to claim 17,
wherein, in the liquid crystal polymer film, in a case where a length of the dispersed phase in a width direction is defined as Lx, a length of the dispersed phase in a longitudinal direction is defined as Ly, and a length of the dispersed phase in a thickness direction is defined as Lz, Expression (2A) and Expression (3A) are satisfied,
$$0.010 \leq Lz / Lx \leq 1. \qquad ( 2 A )$$
$$0.01 0 \leq Lz / Ly \leq 1. 0 . \qquad ( 3 A )$$

20. The liquid crystal polymer film according to claim 2,
wherein, in a case where a viscosity of the liquid crystal polymer film at a temperature lower than a melting point of the liquid crystal polymer film by 30° C. is defined as η(Tm−30° C.) and a viscosity of the liquid crystal polymer film at a temperature higher than the melting point of the liquid crystal polymer film by 30° C. is defined as η(Tm+30° C.), Expression (4A) is satisfied,
$$η ( T m + 30 ° C . ) / η ( Tm - 30 ° C . ) \geq 0.02 . \qquad ( 4 A )$$
